(19) United States
(12) Patent Application Publication
(10) Pub. No.: US 2026/0011665 A1
(43) Pub. Date: Jan. 8, 2026

(54) BUILD UP BONDING LAYER PROCESS AND STRUCTURE FOR LOW TEMPERATURE COPPER BONDING

(71) Applicant: ADEIA SEMICONDUCTOR BONDING TECHNOLOGIES INC., San Jose, CA (US)

(72) Inventor: Gaius Gillman Fountain, JR., Youngsville, NC (US)

(21) Appl. No.: 18/763,467

(22) Filed: Jul. 3, 2024

(51) Int. Cl. H01L 23/00

(52) U.S. Cl. CPC H01L 24/05; H01L 24/03; H01L 24/08; H01L 24/32; H01L 2224/03462; H01L 2224/05567; H01L 2224/05647; H01L 2224/08146; H01L 2224/08235; H01L 2224/32157; H01L 2924/36

(57) ABSTRACT

Disclosed herein are methods of forming a microelectronic component. In some embodiments, the method includes providing an element having a metallization layer that comprises a field dielectric and a conductive feature embedded in the field dielectric. The metallization layer also comprises a surface that includes the field dielectric and the conductive feature. The method further includes forming a copper feature over the conductive feature, forming a dielectric layer over sidewalls of the copper feature, and then planarizing the dielectric layer to form a hybrid bonding surface, where the copper feature is exposed at the hybrid bonding surface.

### BACKGROUND

### Field

This application relates to direct bonding methods and structures, and more particularly to hybrid bonding methods and structures.

### Description of the Related Art

Microelectronic elements, such as integrated device dies or chips, may be mounted or stacked on other elements thereby forming a bonded structure. Direct bonding can be conducted at low temperatures and without external pressure. For example, hybrid bonding involves directly bonding non-conductive features (e.g., inorganic dielectrics) of different elements together, without intervening adhesives, while also directly bonding conductive features (e.g., metal pads) of the elements together. For example, a microelectronic element can be bonded to a carrier, such as a wafer, an interposer, a reconstituted wafer or other element. As another example, a microelectronic element can be bonded on top of another microelectronic element, for example a first integrated device die can be stacked on a second integrated device die. Each of the microelectronic elements can have conductive features, such as pads, for mechanically and electrically bonding the elements to one another. These conductive features are typically formed as part of a direct bonding layer formed on the surface of a metallization layer of the microelectronic elements.

Due to its conductivity, copper is the most common metal in state-of-the-art integrated circuit fabrication. Copper has challenges, such as the difficulty of dry etching copper to produce reliable patterns. For this reason, copper is often patterned by damascene processing, involving the patterning of insulators with trenches, overfilling them with plated copper, and polishing them back to the trench confines.

Other difficulties presented by copper include its high diffusivity in common insulators, such that it can poison semiconductor devices, and its poor adhesion to common insulators, such as silicon oxide based materials, Accordingly, copper features are often lined with adhesion and barrier materials that promote adhesion between copper and the surrounding insulator and prevent copper atoms from the conductive pads from diffusing into the surrounding dielectric material during the process of forming the bonding layer. In a damascene process, the adhesion and barrier materials can be lined in the trench before copper fill. These processes and materials can increase the cost of metallization process and can complicate subsequent bonding.

Accordingly, there is a continuing need for improved methods for forming bonded structures at lower costs.

### BRIEF DESCRIPTION OF THE DRAWINGS

FIG. 1A is a schematic side sectional view of two elements before being directly bonded, according to an embodiment.

FIG. 1B is a schematic side sectional view of the two elements of FIG. 1A after being directly bonded, according to an embodiment.

FIG. 2 is a flowchart illustrating a process of forming a bonded structure that includes hybrid bonded elements, according to some embodiments.

FIGS. 3A-3L are schematic side sectional views of microelectronic elements at various blocks of a process like that of FIG. 2.

FIG. 4 is a flowchart illustrating a process of forming a bonded structure that includes hybrid bonded elements, according to some embodiments.

FIGS. 5A-5L are schematic side sectional views of microelectronic elements at various blocks of a process like that of FIG. 4.

FIG. 6 is a flowchart illustrating a process of forming a bonded structure that includes hybrid bonded elements, according to some embodiments.

FIGS. 7A-7D are schematic side sectional views of microelectronic elements at various blocks of a process like that of FIG. 6.

FIG. 8 is a flowchart illustrating a process of forming a bonded structure that includes hybrid bonded elements, according to some embodiments.

FIGS. 9A-9H are schematic side sectional views of microelectronic elements at various blocks of a process like that of FIG. 8.

FIG. 10 is a flowchart illustrating a process of forming a bonded structure that includes hybrid bonded elements, according to some embodiments.

### DETAILED DESCRIPTION OF THE PREFERRED EMBODIMENT

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023,the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

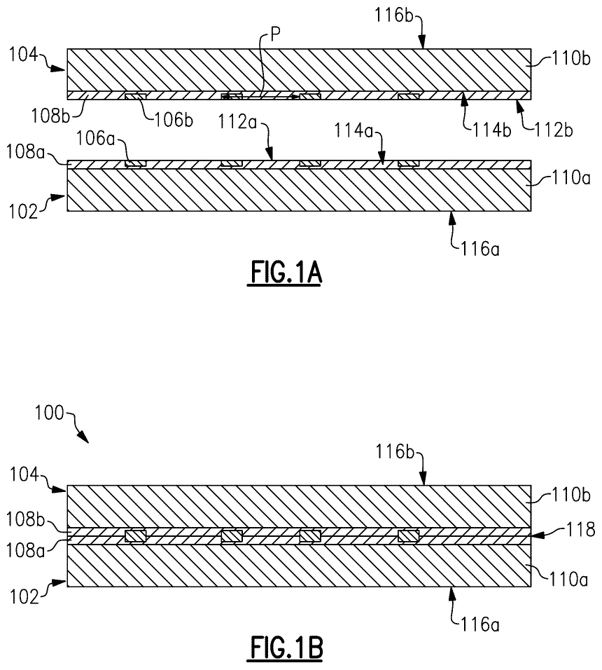

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxycarbonitride, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. Nos. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

As noted in the Background above, copper conductive features for hybrid bonding layers are typically formed using a damascene process. In damascene processes, a dielectric layer is formed and then patterned to form openings in the dielectric layer. An adhesion/barrier layer is deposited in the openings and then copper is deposited over the adhesion/barrier layer. The adhesion/barrier layer is designed to prevent the copper metal from diffusing into the dielectric material during the deposition process and also to improve adhesion between the sidewalls of the opening and the copper metal. In some embodiments, the adhesion/barrier layer can comprise titanium (Ti) or tantalum (Ta). For example, in some embodiments, the adhesion/barrier layer comprises Ti metal and/or TiN or Ta metal and/or TaN.

After depositing the copper metal, a CMP process is then performed to form a bonding surface suitable for hybrid bonding. In some embodiments, a multi-step CMP process is needed due to differences in removal rate for the different material. For example, in some embodiments a first CMP process is performed using a first slurry for bulk overburden removal. The first slurry is typically tuned to copper removal and to permit stopping on the barrier material. Once the barrier on the upper surface is exposed, a second CMP process is typically performed using a second slurry chemistry, where the second slurry chemistry tends to remove copper, barrier and surrounding insulator materials at roughly the same rate. In this second CMP process, the barrier layer and copper metal are polished until they are coplanar with (or recessed below) the non-conductive surface of the dielectric material. Having to use two different slurry chemistries (and two different polishing pads) increases the complexity and costs of performing hybrid bonding.

Accordingly, there is a continued need for improved hybrid bonding processes that do not require multi-step CMP process and two slurry chemistries (and two different polishing pads).

After forming the bonding surface, the element can be hybrid bonded to a second element having a hybrid bonding surface by bringing the bonding surfaces of the two elements together, which can cause direct bonding between the non-conductive surfaces of the hybrid bonding surfaces. As previously discussed, the conductive features of one or both of the elements can be recessed below the non-conductive surfaces such that, when the two hybrid bonding surfaces are initially brought together, the conductive features on the opposing elements are separated from each other by a gap. To cause the conductive features to contact each other, the elements can be annealed to cause the conductive features to expand and contact one another to form a metal-to-metal direct bond. The barrier/adhesion layer(s) between the dielectric material and the copper metal, noted above with respect to damascene copper features, can constrain the expansion of the copper metal because the copper metal can remain adhered to the surrounding insulator by way of the barrier/adhesion layer(s). To ensure that the copper features on the opposing the elements contact each other, the annealing temperature needs to be sufficiently high to allow the copper to plastically deform and expand into contact with one another. However, annealing at too high of a temperature can degrade the performance of the bonded structure due to exceeding the thermal budget of the elements and/or the bonded structure.

Accordingly, there is a continued need for improved hybrid bonding processes that allow for annealing at lower temperatures.

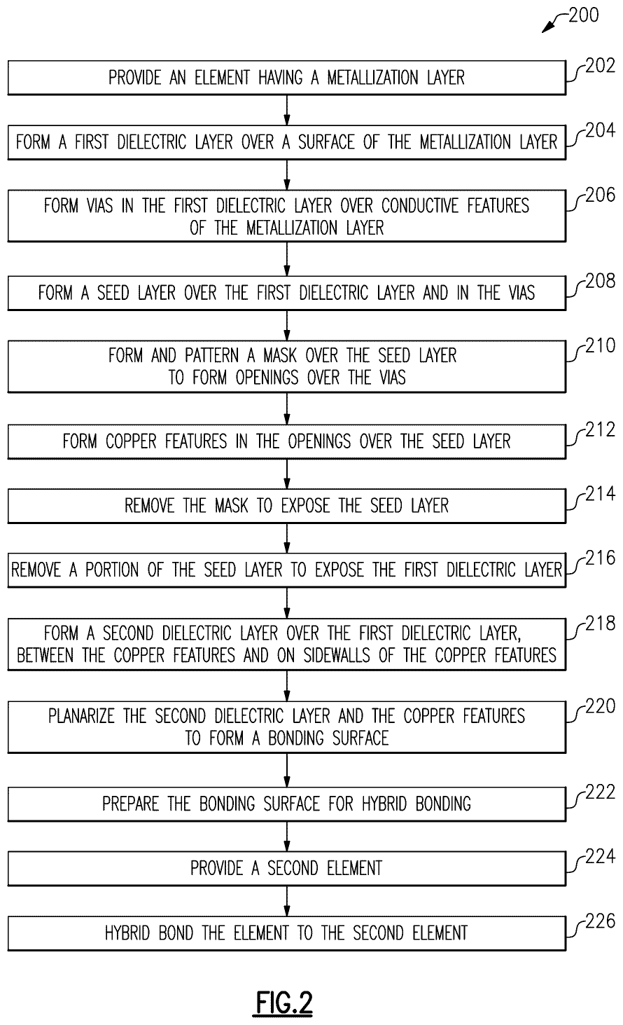

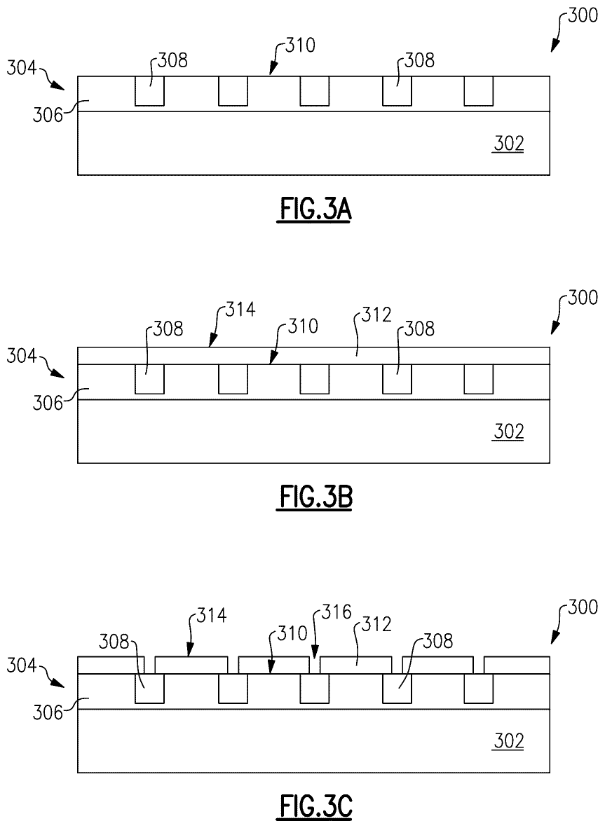

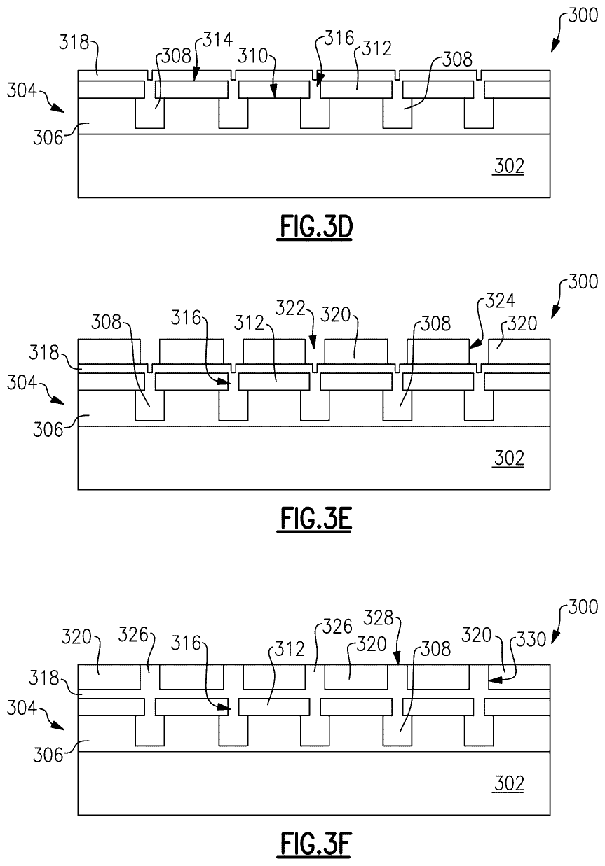

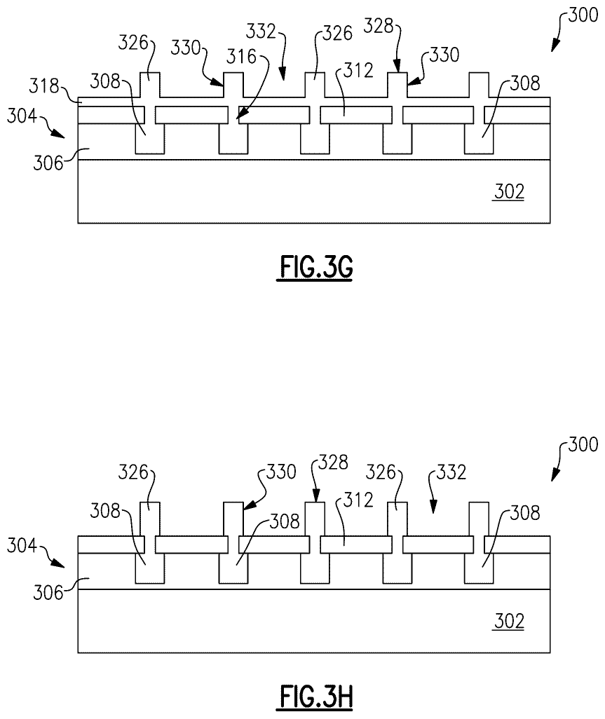

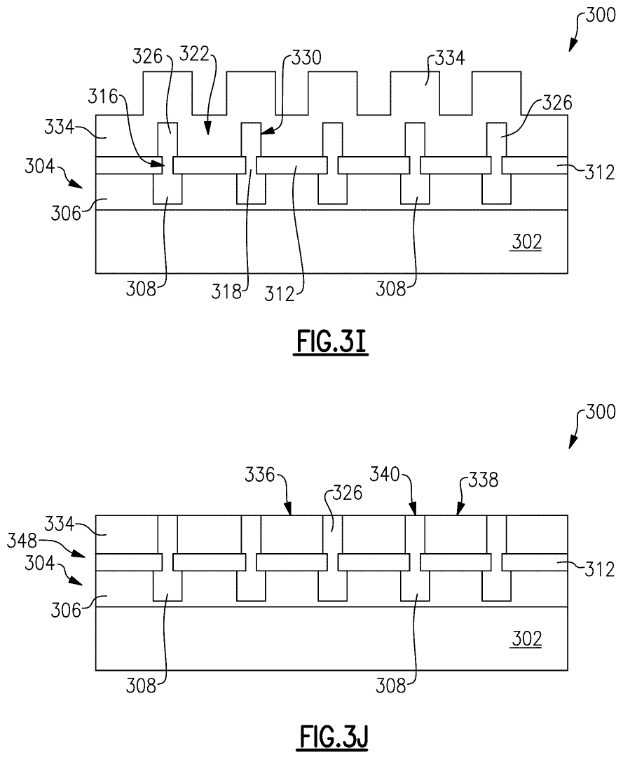

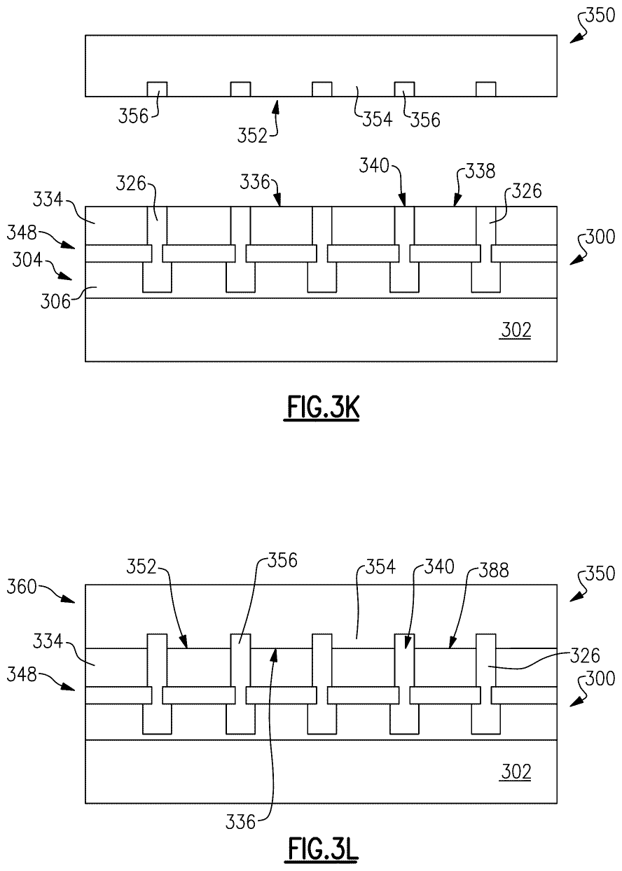

FIG. 2 is a flowchart illustrating a process 200 for forming a microelectronic component that includes forming a bonding layer on an element. FIGS. 3A-3L are schematic side sectional views of microelectronic elements at various blocks of the process 200 shown in FIG. 2.

As shown in FIG. 3A, at block 202, a microelectronic element 300 is provided. The element 300 comprises a base substrate portion 302 and a metallization layer 304 formed over the base substrate portion 302. The metallization layer 304 includes a field dielectric 306 and conductive features 308 formed in the field dielectric 306. The metallization layer 304 has a surface 310 that is defined by the field dielectric 306 and the conductive features 308. In some embodiments, the field dielectric 306 comprises an inorganic dielectric, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. In some embodiments, the field dielectric comprises an organic material, such as a polymer. In some embodiments, the conductive features 308 comprise a conductive metal, such as copper, aluminum, or alloys thereof. In some embodiments, the metallization layer 304 is formed at a back side of the element 300. In other embodiments, the metallization layer 304 is formed at a front side of the element 300, which is the same side of the base substrate 302 as active devices. The illustrated metallization layer 304 can be the uppermost or last metallization layer of a plurality of BEOL metallization layers on a particular side of a microelectronic element. Accordingly, the metallization layer 304 can be formed at a chip foundry, for example, using process nodes typical for BEOL at the foundry, as opposed to a packaging facility.

As shown in FIG. 3B, at block 204, a first dielectric layer 312 is formed over the surface 310 of the metallization layer 304. In some embodiments, the first dielectric layer 312, which forms a surface 314, can completely cover the surface 310, including the field dielectric 306 and the conductive feature 308. In some embodiments, the first dielectric layer 312 comprises an inorganic dielectric material or a barrier dielectric material, such as silicon oxide, silicon nitride, or silicon oxynitride, or can include carbon, such as silicon carbide silicon oxycarbonitride, low K dielectric materials, SiCOH dielectrics, silicon carbonitride or diamond-like carbon or a material comprising a diamond surface. In some embodiments, the field dielectric 306 need not be a barrier material, and can be a lower stress, lower dielectric material such as a silicon oxide based material. In some embodiments, the first dielectric layer 312 can be formed over the surface 310 such that the first dielectric layer 312 has a thickness of less than 1 μm. In other embodiments, however, the first dielectric layer 312 can have a different thickness. For example, in some embodiments, the first dielectric layer 312 has a thickness of 5 μm or less, 2 μm or less, 1 μm or less, 0.5 μm or less, or any other suitable thickness. In some embodiments, the first dielectric layer 312 can be formed by depositing the dielectric material over the surface 310 and then thinning the dielectric material to a desired thickness. In some embodiments, after depositing the dielectric material, the dielectric material can be planarized.

As shown in FIG. 3C, at block 206, vias 316 are formed in the first dielectric layer 312. The vias 316 extend completely through the first dielectric layer 312 to expose at least a portion of the conductive features 308. In some embodiments, the vias 316 are formed by patterning and etching the first dielectric layer 312. In some embodiments, the vias 316 are formed over one or more of the conductive features 308 in the first dielectric layer 312 such that, after forming the vias 316 the conductive features 308 are exposed through the first dielectric layer 312. In some embodiments, the vias 316 may only be formed over some of the conductive features 308 such that, after forming the vias 316, one or more of the conductive features 308 are not exposed through the first dielectric layer 312. In other embodiments, the vias 316 are formed over all of the conductive features 308 such that, after forming the vias 316, all of the conductive features 308 are exposed through the first dielectric layer 312. In some embodiments, the vias 316 are sized such that only a portion of the surfaces of the underlying conductive features 308 are exposed, as shown, to reduce misalignment problems. In other embodiments, the vias 316 are sized such that the entire surface of each of the underlying conductive features 308 is exposed. In some embodiments, the field dielectric 306 is not exposed by the vias 316. In other embodiments, the vias 316 are sized and/or positioned such that a portion of the field dielectric 306 is exposed by the vias 316.

As shown in FIG. 3D, at block 208, a seed layer 318 is formed over the metallization layer 304 and the first dielectric layer 312 such that the seed layer 318 is formed in the vias 316 and over the surface 314 of the first dielectric layer 312. The seed layer 318 comprises a conductive metal such as copper metal or aluminum metal. In some embodiments, the seed layer 318 comprises the same conductive metal that the conductive features 308 are formed from. For example, in embodiments where the conductive features comprise copper, the seed layer 318 can also comprise copper. In other embodiments, the seed layer 318 comprises a different conductive metal. For example, in embodiments where the conductive features 308 comprise aluminum metal, the seed layer 318 can comprise copper.

The seed layer 318 is formed by blanket depositing the conductive metal over the metallization layer 304 and the first dielectric layer 312 such that the conductive metal covers the first dielectric layer 312, directly contacts the conductive features 308 of the metallization layer 304, and at least partially fills the vias 316. In some embodiments, the seed layer 318 completely fills the vias 316. In other embodiments, however, the seed layer only partially fills the vias 316.

As shown in FIG. 3E, at block 210, a mask 320 is formed over the seed layer 318 and then patterned to form openings 322 in the mask 320. The mask 320 can be formed from any suitable material, such as resist, and can be patterned using any suitable patterning technique. For example, in some embodiments, the mask 320 can be patterned by selectively irradiating and developing a photoresist layer, or a patterned resist can have its pattern extended down into a hard mask material. The openings 322 can extend through the mask 320 and can be formed over the conductive features 308 such that the portions of the seed layer 318 in the vias 316 are exposed through the openings 322. In the illustrated embodiment, the openings 322 are wider than the vias 316. In other embodiments, however, the openings 322 can have approximately the same width as the vias 316 or can be narrower than the vias 316.

In some embodiments, the openings 322 can have a straight profile such that the width of the openings 322 near the seed layer 318 can be approximately the same as the width of the openings 322 near the top surface of the mask 320. In these embodiments, the sidewalls 324 of the mask 320 are generally vertical and are generally perpendicular to the surface 314 of the first dielectric layer 312. In other embodiments, however, the openings 322 can have a different profile. For example, in some embodiments, the openings 322 can have a V-shaped profile where the width of the openings 322 near the seed layer 318 is less than the width of the openings 322 near the top surface of the mask 320 due to the process of patterning the mask 320. In these embodiments, the sidewalls 324 can be angled away from vertical such that the sidewalls 324 form an angle greater than 90° with the upper surface of the mask 320. In some embodiments, the profile of the openings can depend on the process used to pattern the openings 322 in the mask 320 and/or the material from which the mask 320 is formed. In some embodiments, sidewalls 324 of the openings 322 can have an undulating profile due to standing waves during exposure of photoresist for patterning.

As shown in FIG. 3F, at block 212, copper features 326 are formed in the openings 322. The copper features 326 directly contact the seed layer 318 and have sidewalls 330 that contact the sidewalls 324 (FIG. 3E) of the mask 320. In some embodiments, the copper features 326 completely cover the portions of the seed layer 318 formed in the vias 316 over the conductive features 308. In some embodiments, the copper features 326 are formed in the openings 322 by plating (e.g., electroplating) copper metal into the openings 322. In some embodiments, the copper features 326 completely fill the openings 322 such that surfaces 328 of the copper features 326 are roughly coplanar with the top surface of the mask 320. In other embodiments, however, the copper features 326 do not completely fill the openings 322 such that the surfaces 328 are recessed below the top surface of the mask 320.

In the illustrated embodiment, the copper features 326 have a straight profile such that the sidewalls 330 are generally straight and vertical. In other embodiments, however, one or more of the copper features 326 can have a different profile and the sidewalls 330 can have a different shape and/or orientation. For example, in some embodiments, one or more of the copper features 326 can have a V-shaped profile such that the sidewalls 330 flare outwards towards the upper surface 328. In these embodiments, the width of the copper features 326 can be greater at positions near the surface 328 than at positions further from the surface 328 and the sidewalls 330 can form an angle that is less than 90° with the surface 328. In some embodiments, the copper features 326 can have the inverse profile as the profile of sidewalls 324 of the openings 322 and the sidewalls 330 can have the same shape and/or orientation as the sidewalls 324 of the mask 320. In general, the copper features 326 can have any suitable shape. In some embodiments, the skilled artisan can determine that the features 326 were formed by electroplating through a resist mask, as opposed to filling an opening in an inorganic that remains in place. For example, to the extent the sidewalls 324 of the mask 320 had an undulating profile due to standing waves during exposure of photoresist for patterning, that shape can be replicated by copper features 326, unlike a damascene feature.

As shown in FIG. 3G, at block 214, the mask 320 is removed (e.g., resist stripped) to expose a portion of the seed layer 318 and to expose the sidewalls 330 of the copper features 326. After removing the mask 320, the copper features 326 can be separated from each other by gaps 332, which can extend between adjacent copper features 326. The mask 320 can be removed using any suitable selective process, such as a resist strip chemistry if the mask is formed from resist.

As shown in FIG. 3H, at block 216, a portion of the seed layer 318 (e.g., the portion exposed by removing the mask 320) is removed to expose the first dielectric layer 312. In some embodiments, removing the portion of the seed layer 318 to expose the first dielectric layer 312 comprises removing the portion of the seed layer 318 that is not covered by the copper features 326. In some embodiments, removing the portion of the seed layer 318 comprises etching away the portion of the seed layer 318 by exposing the portion of the seed layer 318 to an etchant. In some embodiments, etching away the portion of the seed layer 318 comprises wet etching (e.g., blanket wet etching) or dry etching the portion of the seed layer 318. In some embodiments, exposing the portion of the seed layer 318 to the etchant results in a portion the copper features 326 (e.g., a portion of the sidewalls 330 and/or the surface 328) being exposed to the etchant. In these embodiments, the etchant can also remove some of the copper metal from the copper features 326 during the etching process. Because the seed layer 318 is thin relative to the copper features 326, its removal does not significantly damage the copper features 326. In some embodiments, the etchant is configured to selectively etch copper metal without etching dielectric materials. In these embodiments, exposing the portion of the seed layer 318 to the etchant can result in the surface 314 of the first dielectric layer 312 not being etched (or not being significantly etched). In other embodiments, however, the etchant can slightly or completely etch dielectric materials. In such embodiments, exposing the seed layer 318 to the etchant can result in at least some of the surface 314 also being removed by the etchant.

While FIG. 3H and other embodiments herein show the result of a blanket etch, it will be understood that in other variants of all the embodiments herein, another mask can be provided to protect the copper features during removal of the seed layer. In such variants, the mask may be wider than the copper features to increase mask misalignment tolerance, and small wings or rings of the seed layer may remain extending from the base of the copper features over the first dielectric layer.

As shown in FIG. 3I, at block 218, a second dielectric layer 334 is formed over the first dielectric layer 312 and the copper features 326. The second dielectric layer 334 is formed in the gaps 332 between the adjacent copper features 326 and, in some embodiments, completely fills the gaps 332. While illustrated as a conformal deposition, such as chemical vapor deposition (CVD), in which significant undulations are left by the dielectric layer 334 overlying the copper features 326, the skilled artisan will understand that in other embodiments a self-leveling dielectric can be employed, such as spin-on glass (SOG). The second dielectric layer 334 directly contacts the sidewalls 330 of the copper features 326 and, in some embodiments, on the surfaces 328 of the copper features 326. In some embodiments, the second dielectric layer 334 comprises an oxide material (e.g., an inorganic oxide material), such as a silicon oxide based material. For example, in some embodiments, the second dielectric layer 334 comprises silicon oxide (SiO₂), silicon oxynitride, silicon oxycarbide, or doped silicon oxide, such as F-doped SiO₂, borosilicate glass (BSG), or borophosphosilicate glass (BPSG). When the second dielectric layer 334 is formed over the copper features 326, the oxide material directly contacts the sidewalls 330 of the copper features 326. When the oxide material contacts the sidewalls 330, the oxide material can react with the copper metal that forms the sidewalls 330 to form copper oxide (e.g., Cu₂O, CuO). Accordingly, after forming the second dielectric layer 334 over the first dielectric layer 312 and the copper features 326, a layer of copper oxide can be formed on the sidewalls 330 of the copper features 326 between copper of the copper features 326 and the second dielectric layer 334.

As discussed in greater detail elsewhere in this application, copper or copper oxide weakly adheres to the dielectric material that forms the second dielectric layer 334, which means that the adhesion force between the dielectric material and the copper metal of the copper features 326 is reduced. The lower adhesion allows for a lower annealing temperature (e.g., an annealing temperature less than 250° C.) to be used in a subsequent annealing step as part of hybrid bonding because the expansion of the copper metal is less constrained by adhesion between copper of the copper features 326 and the surrounding dielectric layer 334. Without barrier/adhesion layer(s), the copper can expand and slide with respect to the surrounding dielectric layer 334 and need not be heated sufficiently for plastic deformation. Accordingly, forming the second dielectric layer 334 such that the dielectric material directly contacts the sidewalls 330 of the copper features 326 can allow for low-temperature annealing for subsequent hybrid bonding, which means that any performance degradation of the element and/or bonded structure due to exceeding the thermal budget of the element and/or bonded structure can be reduced or even avoided.

As shown in FIG. 3J, at block 220, the second dielectric layer 334 and the copper features 326 are planarized to form a bonding surface 336. In some embodiments, planarizing the second dielectric layer 334 comprises completely removing the portion of the second dielectric layer 334 formed above the copper features 326 to expose the copper features 326. In some embodiments, planarizing the second dielectric layer 334 also comprises removing some of the portion of the second dielectric layer 334 that is formed in the gaps 332. In some embodiments, planarizing the copper features 326 comprises removing at least some of the copper metal that forms the copper features 326.

The second dielectric layer 334 and the copper features 326 can be planarized using any suitable planarization process. For example, in some embodiments, the planarization process comprises a CMP process that involves using a polishing pad and a slurry to polish the second dielectric layer 334 and the copper features 326 to form the bonding surface 336. Additionally, unlike in conventional damascene processes where copper overburden from plating is to be removed, the CMP process need not remove significant amounts of copper prior to planarization and can be performed with a single polishing pad and a single slurry chemistry. Although no barrier is present in the illustrated embodiment, the slurry can be the same as those termed a “barrier slurry” in the industry, as it is tuned to remove oxides and copper at roughly the same rates, or to slightly recess copper. After performing the CMP process using the single polishing pad and the single slurry chemistry, the top surface of the copper features 326 can be recessed below the top surface of the second dielectric layer 334.

After preparation for hybrid bonding, such as activation and/or termination as described above and below, the bonding surface 336 comprises a hybrid bonding surface that includes a dielectric field region 338 and contact regions 340, where the dielectric field region 338 comprises the second dielectric layer 334 and the contact regions 340 are formed from the exposed surfaces of the copper features 326. In some embodiments, after planarizing the second dielectric layer 334 and the copper features 326, the contact regions 340 are flush with the dielectric field region 338. In other embodiments, however, the contact regions 340 are recessed below the dielectric field region 338 uniformly across the element 300. In still other embodiments, the contact regions 340 protrude above dielectric field region 338 uniformly across the element 300.

The first dielectric layer 312, the second dielectric layer 334, copper features 326, and the conductive vias 316 define a bonding layer 348 of the element 300. The bonding layer 348 includes the bonding surface 336 and is formed on the surface 310 of the metallization layer 304. However, the bonding layer 348 does not include a barrier layer between sidewalls the copper features 326 and the second dielectric layer 334. Accordingly, the second dielectric layer 334, which can include silicon oxide, directly contacts the sidewalls 330 of the copper features 326, which can also result in the formation of copper oxide forming on the sidewalls 330 of the copper features 326, and either copper or copper oxide has relatively poor adhesion to the second dielectric layer 334 compared to damascene pads.

At block 222, the bonding surface 336 is prepared for hybrid bonding. In some embodiments, preparing the bonding surface 336 for hybrid bonding comprises polishing the bonding surface 336 to a high degree, as described above. In some embodiments, preparing the bonding surface 336 comprises activating the bonding surface 336. In some embodiments, activating the bonding surface 336 comprises plasma activating the bonding surface 336 by exposing the bonding surface 336 to one or plasmas, such as a nitrogen plasma and/or an oxygen plasma, or by slight etching. In some embodiments, the activation or other process can result in terminating species, such as nitrogen, that can increase bonding strength. In some embodiments, activating the bonding surface 336 comprises chemically activating the bonding surface. In some embodiments, preparing the bonding surface 336 for hybrid bonding comprises rinsing the bonding surface 336 to remove any particulate matter on the bonding surface 336, and then drying the bonding surface 336. Activation can sometimes be omitted, particularly if the other surface to be hybrid bonded to the bonding surface 336 is activated. Termination can also be provided separately from or without plasma activation, such by ammonium dip.

As shown in FIG. 3K, at block 224, a second element 350 is provided. In some embodiments, the second element 350 can be a reconstituted element/wafer. The second element 350 comprises a bonding surface 352, a dielectric field region 354, and conductive features 356, where the bonding surface 352 includes the conductive features 356 and the dielectric field region 354. The bonding surface 352 can be activated and/or terminated and prepared for hybrid bonding with element 300. In some embodiments, both the bonding surface of the second element 350 and the bonding surface 336 of the element 300 are activated and/or terminated. In some embodiments only one of the bonding surfaces 336, 352 is activated. The conductive features 356 comprise a conductive metal. For example, in some embodiments, the conductive metal comprises copper, aluminum, tin, nickel, gold, or an alloy of one or more of these elements. In some embodiments, the dielectric field region 354 comprises an inorganic dielectric material, such as silicon oxide, silicon nitride, silicon oxynitride, and can include carbon, such as silicon carbide, silicon oxycarbonitride, low K dielectric materials, SiCOH dielectrics, silicon carbonitride, diamond-like carbon, a material comprising a diamond surface, or combinations thereof. In some embodiments, the dielectric field region 354 comprises the same dielectric material as the second dielectric layer 334; in other embodiments the bonding dielectrics of the two substrates are different.

In some embodiments, the second element 350 can have a structure that is generally similar to the structure of element 300, which can also be referred to as the first element 300. For example, in some embodiments, the conductive features 356 comprise copper metal, the field dielectric region 354 comprises an oxide material, and the second element 350 does not include an adhesion and/or barrier layer between the sidewalls of the conductive features 356 and the oxide material of the field dielectric region 354. Additionally, copper oxide can be formed between the sidewalls of the conductive features 356 and the field dielectric region 354. The lack of adhesion and/or barrier materials, and/or presence of copper oxide at the sidewalls, can result in reduced adhesion between the conductive features 356 and the field dielectric region 354. In some embodiments, one or more of the conductive features 356 is recessed below the bonding surface 352. In other embodiments, the conductive features 356 are generally coplanar with the dielectric field region 354 or protrude above (or below in the orientation of FIG. 3K) the dielectric field region 354. In general, the second element 350 can have any structure that is suitable for hybrid bonding with the element 300, including conventional damascene conductive features with adhesion and/or barrier materials at the sidewalls.

As shown in FIG. 3L, at block 226, the element 300 is hybrid bonded to the second element 350 to form bonded structure 360. The element 300 is hybrid bonded to the second element 350 without an intervening adhesive. The element 300 can be hybrid bonded to the second element 350 by contacting the bonding surface 352 of the second element to the bonding surface 336 so that the dielectric field region 338 of the bonding surface 336 and the dielectric field region 354 of the bonding surface 352 contact each other, which can cause chemical bonds (e.g., covalent bonds) to occur spontaneously between the dielectric material of the dielectric field region 338 and the dielectric material of the dielectric field region 354, even at room temperature and without external pressure beyond initiating contact. In some embodiments, hybrid bonding the element 300 to the second element 350 can include annealing the elements 300 and 350 to cause the contact regions 340 to contact the conductive features 356. In some embodiments, annealing the elements 300 and 350 causes one or both of the copper features 326 and the conductive features 356 to expand and contact each other, resulting in the materials of the contact regions 340 inter-diffusing with the materials of the opposing conductive features 356. In some embodiments, annealing the elements 300 and 350 can also increase the strength of the chemical bonds between the dielectric field region 338 and the dielectric field region 354. In some embodiments, due at least in part to the reduced adhesion between the copper features 326 and the second dielectric layer 334, annealing the first element 300 and the second element 350 can be performed at a temperature of 250° C. or less. In other embodiments, however, the elements 300, 350 can be annealed at a different temperature. For example, in some embodiments, hybrid bonding the first element 300 to the second element 350 comprises annealing the first and second elements 300, 350 at a temperature of 300° C. or less, 250° C. or less, 200° C. or less, 150° C. or less, 100° C. or less, a temperature between 50° C. and 300° C., a temperature between 100° C., and 250° C., a temperature between 150° C. and 200° C., or a temperature in a range defined by any of the values.

After hybrid bonding the element 300 to the second element 350 to form the bonded structure 360, the bonded structure 360 can undergo additional processing. For example, in some embodiments, the bonded structure 360 can be singulated to form one or more singulated bonded structures and/or can be bonded to one or more other elements (e.g., dies, substrates, wafers, etc.). In some embodiments, the additional processing can include thinning the bonded structure 360 (either before or after being singulated and/or bonded to another element or after). For example, in some embodiments, the backsides of one or both of elements 300, 350 (e.g., the sides of the elements 300, 350 opposite from the bonding surfaces 336, 352) can be thinned. In some embodiments, after thinning, the backsides of one or both of the elements 300, 350 can be etched to reveal TSVs or other metallization structures within the elements 300, 350. In some embodiments, the additional processing can include processing the backside of one or both of the elements 300, 350 to form one or more bonding surfaces. In some embodiments, a conductive barrier layer can be formed between one or more of the exposed metallization structures and the deposited conductive layer. In some embodiments, one or more other elements (e.g., dies, substrates, wafers, etc.) can be bonded to the backside (e.g., to the bonding surface or the conductive layer) of one or both of the elements 300, 350.

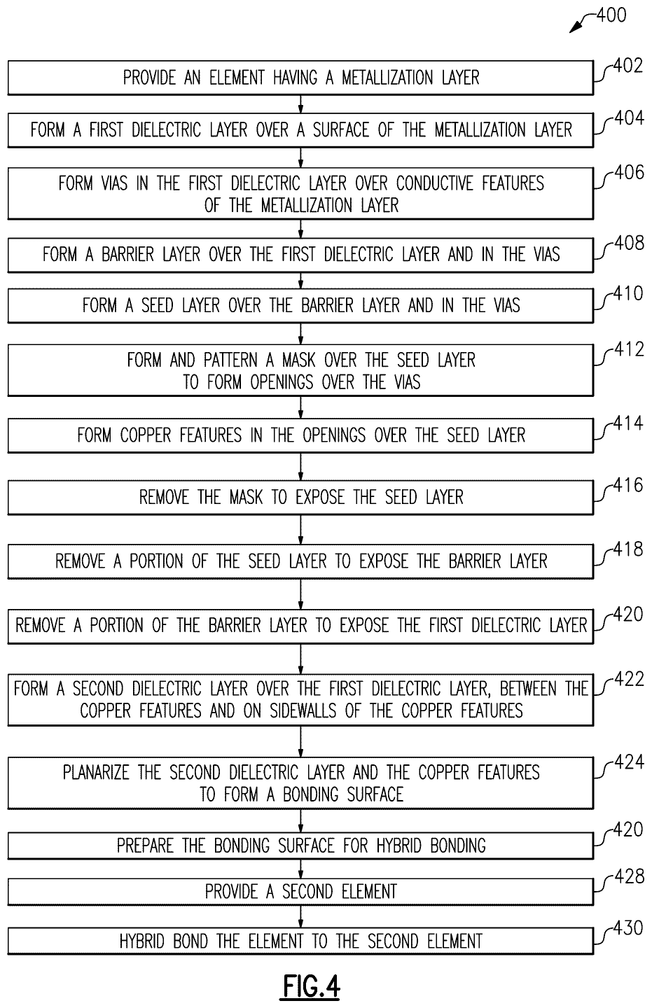

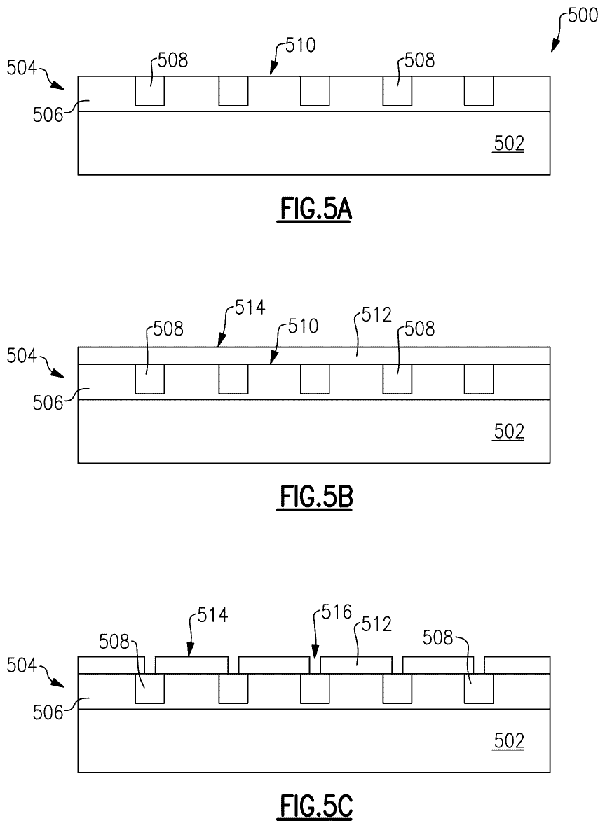

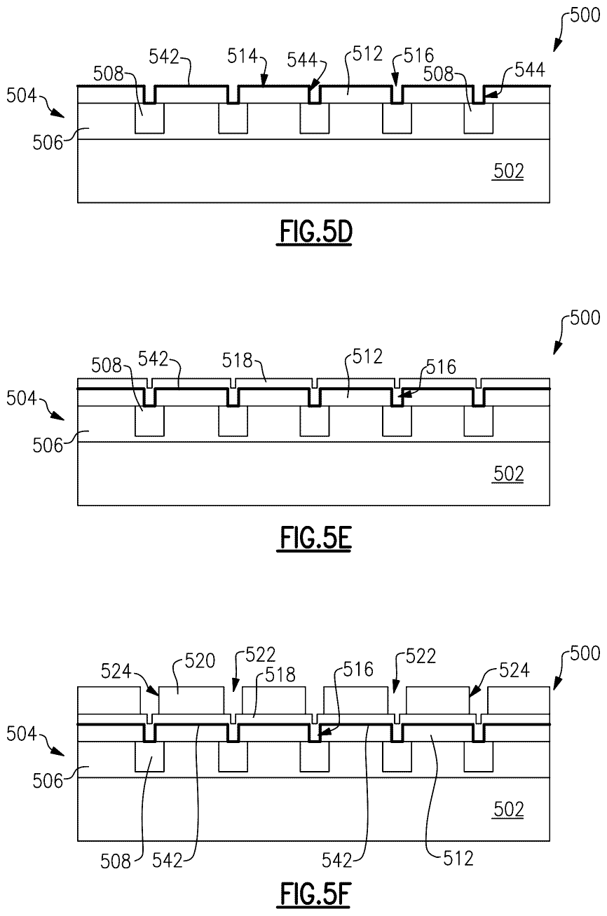

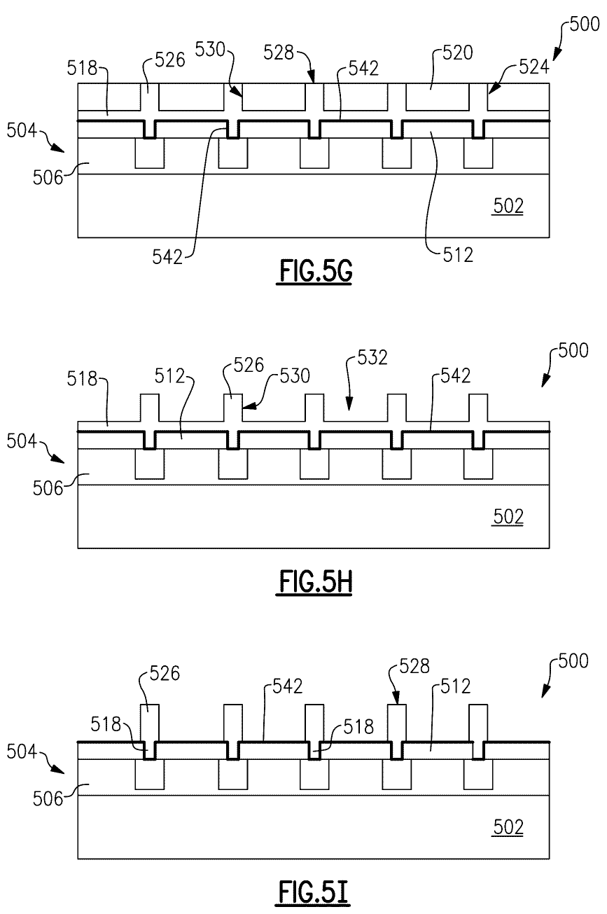

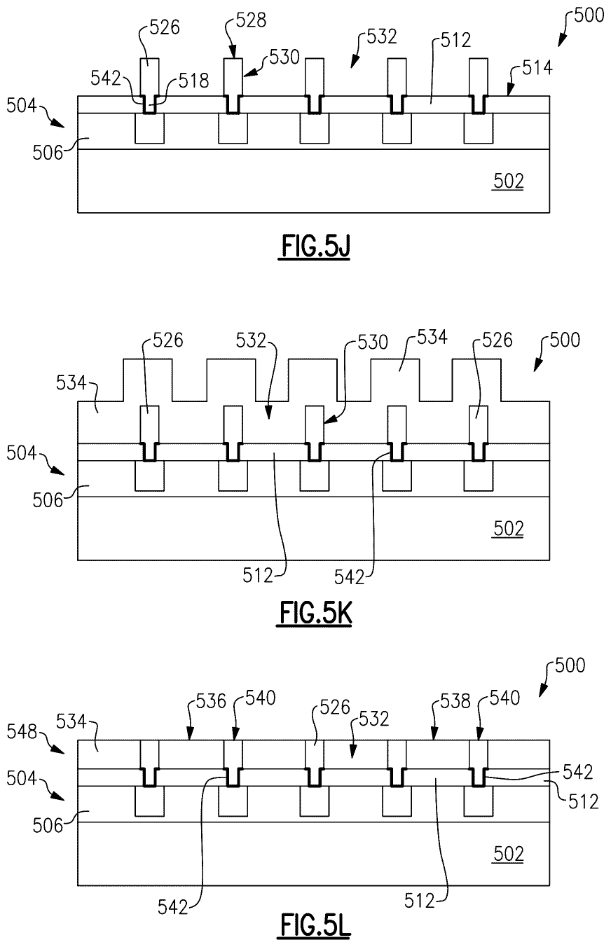

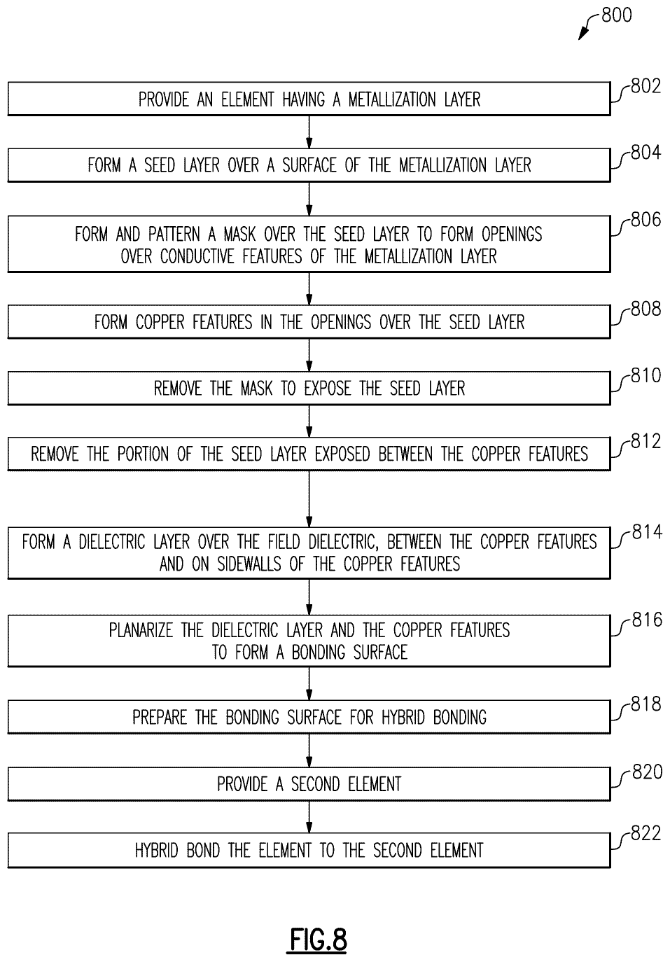

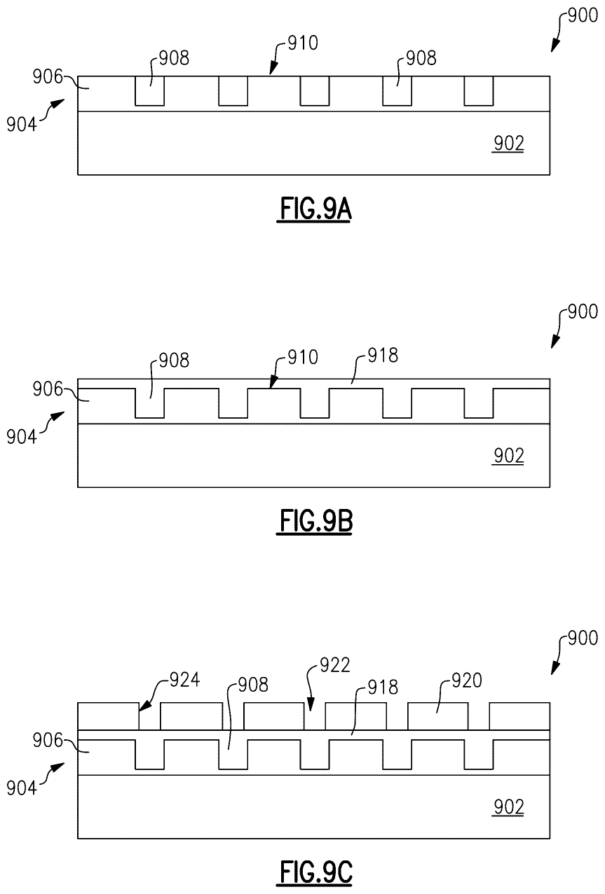

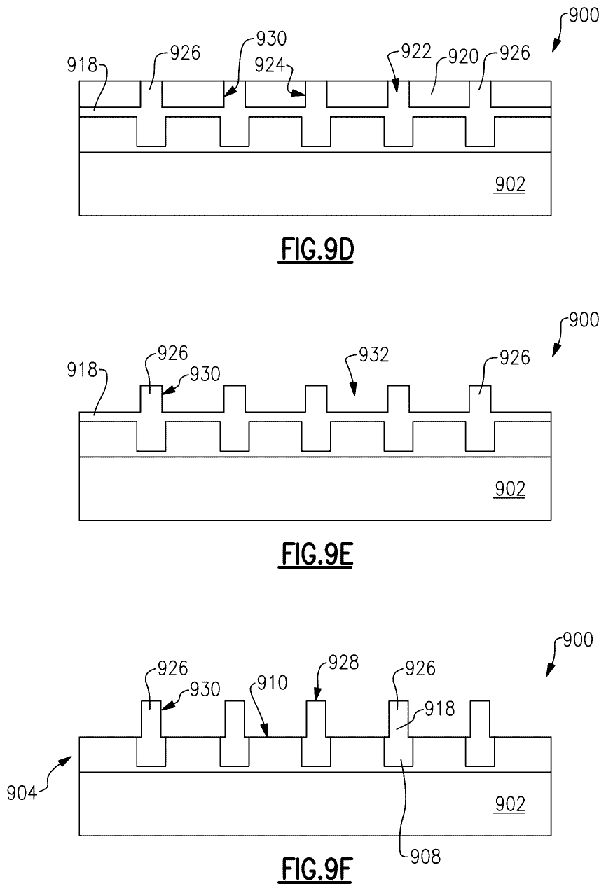

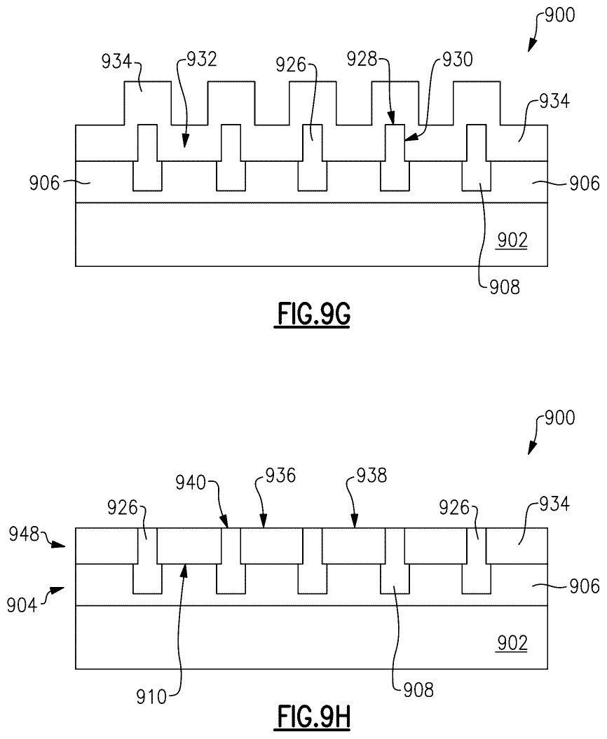

In the embodiment illustrated in FIGS. 2-3L, the seed layer 318 (FIG. 3D) is formed such that it directly contacts the first dielectric layer 312 and the portions of the conductive features 308 that are exposed through the vias 316. However, depending upon the materials selected, the metal from the seed layer 318 can undesirably diffuse into the dielectric material of the first dielectric layer 312. FIG. 4 is a flowchart illustrating a process 400 for forming a microelectronic component that includes forming a bonding layer on an element and that has a barrier layer under the seed layer that reduces (or even prevents) diffusion of the metal from the seed layer into the dielectric layer during the deposition process. This can advantageously widen selection of materials for the dielectric material under the seed layer and/or the seed layer itself, or can facilitate elimination of a separate dielectric layer under the seed layer (see FIGS. 8-9H and attendant description). FIGS. 5A-5L are schematic side sectional views of microelectronic elements at various blocks of the process 400 shown in FIG. 4.

As shown in FIG. 5A, at block 402, a microelectronic element 500 is provided. The element 500, which can be generally similar to the element 300 shown and described in connection with FIG. 3A, comprises a base substrate portion 502 and a metallization layer 504 formed over the base substrate portion 502. The metallization layer 504 includes a field dielectric 506 and conductive features 508 formed in the field dielectric 506. The metallization layer 504 has a surface 510 that is defined by the field dielectric 506 and the conductive features 508. In some embodiments, the field dielectric 506 comprises an inorganic dielectric, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. In some embodiments, the conductive features 508 comprise a conductive metal, such as copper, aluminum, or alloys thereof. In some embodiments, the metallization layer 504 is formed at a back side of the element 500. In other embodiments, the metallization layer 504 is formed at a front side of the element 500, closer to active devices. The illustrated metallization layer 504 can be the uppermost or last metallization layer of a plurality of BEOL metallization layers on a particular side of a microelectronic element. Accordingly, the metallization layer 504 can be formed at a chip foundry, for example, using process nodes typical for BEOL at the foundry, as opposed to a packaging facility.

As shown in FIG. 5B, at block 404, a first dielectric layer 512 is formed over the surface 510 of the metallization layer 504. In some embodiments, the first dielectric layer 512, which forms a surface 514, can completely cover the surface 510, including the field dielectric 506 and the conductive feature 508. In some embodiments, the first dielectric layer 512 comprises an inorganic dielectric material or a barrier dielectric material, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. In some embodiments, the field dielectric 506 need not be a barrier material, and can be a lower stress, lower dielectric material such as a silicon oxide based material. In some embodiments, the first dielectric layer 512 can be formed over the surface 510 such that the first dielectric layer 512 has a thickness of less than 1 μm. In other embodiments, however, the first dielectric layer 512 can have a different thickness. For example, in some embodiments, the first dielectric layer 512 has a thickness of 5 μm or less, 2 μm or less, 1 μm or less, 0.5 μm or less, or any other suitable thickness. In some embodiments, the first dielectric layer 512 can be formed by depositing the dielectric material over the surface 510 and then thinning the dielectric material to a desired thickness. In some embodiments, after depositing the dielectric material, the dielectric material can be planarized.

As shown in FIG. 5C, at block 406, vias 516 are formed in the first dielectric layer 512. The vias 516 extend completely through the first dielectric layer 512 to expose at least a portion of the conductive features 508. In some embodiments, the vias 516 are formed by patterning and etching the first dielectric layer 512. In some embodiments, the vias 516 are formed over one or more of the conductive features 508 in the first dielectric layer 512 such that, after forming the vias 516 the conductive features 508 are exposed through the first dielectric layer 512. In some embodiments, the vias 516 may only be formed over some of the conductive features 508 such that, after forming the vias 516, one or more of the conductive features 508 are not exposed through the first dielectric layer 512. In other embodiments, the vias 516 are formed over all of the conductive features 508 such that, after forming the vias 516, all of the conductive features 508 are exposed through the first dielectric layer 512. In some embodiments, the vias 516 are sized such that only a portion of the surfaces of the underlying conductive features 508 are exposed, as shown, to minimize misalignment issues. In other embodiments, the vias 516 are sized such that the entire surface of each of the underlying features 508 is exposed. In some embodiments, the field dielectric 506 is not exposed by the vias 516. In other embodiments, the vias 516 are sized and/or positioned such that a portion of the field dielectric 506 is exposed by the vias 516.

As shown in FIG. 5D, at block 408, a barrier layer 542 is formed over the metallization layer 504 and the first dielectric layer 512. In some embodiments, the barrier layer 542 comprises a conductive barrier material, such as a barrier metal, barrier alloy, or barrier metal nitride. For example, in some embodiments, the barrier layer 542 comprises one or more of titanium metal, titanium nitride, tantalum metal, tantalum nitride, ruthenium, tungsten, titanium-tungsten alloy, etc. The barrier layer 542 is formed by depositing the conductive barrier material over the metallization layer 504 and the first dielectric layer 512 such that the conductive barrier material covers the surface 514 of the first dielectric layer 512, directly contacts the conductive features 508 of the metallization layer 504, and lines the sidewalls 544 of the vias 516. In some embodiments, the barrier layer 542 completely covers the sidewalls 544 of the vias 516. In some embodiments, the barrier layer 542 completely covers the surface 514 of the first dielectric layer 512. In other embodiments, the barrier layer 542 only partially covers the surface 514. In the illustrated embodiment, the vias 516 are formed such that only a portion of the conductive features 508 are exposed in the vias. Accordingly, the barrier layer 542 only covers the exposed portions of the conductive features 508. In embodiments where the entire surface of the conductive features 508 are exposed by the vias, the barrier layer 542 can cover the entire surface of the conductive features 508. Similarly, in embodiments where a portion of the field dielectric 506 is exposed by the vias 516, the barrier layer 542 can also cover the exposed portions of the field dielectric 506.

As shown in FIG. 5E, at block 410, a seed layer 518 is formed on the barrier layer 542. The seed layer 518 is formed in the vias 516 and over the surface 514 of the first dielectric layer 512. In some embodiments, the seed layer 518 comprises a conductive metal. For example, in some embodiments, the seed layer 518 comprises copper metal or aluminum metal. The seed layer 518 is formed by blanket depositing the conductive metal over the barrier layer 542 such that the conductive metal at least partially covers the barrier layer 542 and at least partially fills the vias 516. However, in the illustrated embodiment, the seed layer 518 does not contact the first dielectric layer 512 because the barrier layer 542 is positioned between the first dielectric layer 512 and the seed layer 518. In some embodiments, the seed layer 518 completely fills the vias 516. In other embodiments, however, the seed layer 518 only partially fills the vias 516.

As shown in FIG. 5F, at block 412, a mask 520 is formed over the seed layer 518 and then patterned to form openings 522 in the mask 520. The mask 520 can be formed form any suitable material, such as resist, and can be patterned using any suitable patterning technique. For example, in some embodiments, the mask 520 can be patterned by selectively irradiating and developing a photoresist layer, or a patterned resist can have its pattern extended down into a hard mask material. The openings 522 can extend through the mask 520 and can be formed over the conductive features 508 such that the portions of the seed layer 518 in the vias 516 are exposed through the openings 522. In the illustrated embodiment, the openings 522 are wider than the vias 516. In other embodiments, however, the openings 522 can have approximately the same width as the vias 516 or can be narrower than the vias 516. The openings 522 have sidewalls 524 and can have a straight profile, a V-shaped profile, or any other suitable profile and, in some embodiments, the profile can depend on the process used to pattern the openings 522 in the mask 520 and/or the material from which the mask 520 is formed. As noted above, in some embodiments the sidewalls 524 can evince undulations from standing waves during exposure of photoresist for patterning.

As shown in FIG. 5G, at block 414, copper features 526 are formed in the openings 522. The copper features 526 directly contact the seed layer 518 and have sidewalls 530 that contact the sidewalls 524 of the mask 520. In some embodiments, the copper features 526 completely cover the portions of the seed layer 518 formed in the vias 516 over the conductive features 508. In some embodiments, the copper features 526 are formed in the openings 522 by plating (e.g., electroplating) copper metal into the openings 522. In some embodiments, the copper features 526 completely fill the openings 522 such that a surface 528 of the copper features 526 is generally coplanar with the top surface of the mask 520. In other embodiments, however, the copper features 526 do not completely fill the openings 522 such that the surface 528 is recessed below the top surface of the mask 520. The copper features 526 can have a straight profile, a V-shaped profile, or any other suitable profile. In general, the copper features 526 can have any suitable shape. In some embodiments, the skilled artisan can determine that the features 526 were formed by electroplating through a resist mask, as opposed to filling an opening in an inorganic insulator that remains in place. For example, to the extent the sidewalls 524 of the mask 520 had an undulating profile due to standing waves during exposure of photoresist for patterning, that shape can be replicated by copper features 526, unlike a damascene feature.

As shown in FIG. 5H, at block 416, the mask 520 is selectively removed to expose a portion of the seed layer 518 and to expose the sidewalls 530 of the copper features 526. After removing the mask 520, the copper features 526 can be separated from each other by gaps 532, which can extend between adjacent copper features 526. The mask 520 can be removed by any suitable process, such as resist stripping if the mask comprises resist.

As shown in FIG. 5I, at block 418, a portion of the seed layer 518 (e.g., the portion exposed in the gaps 532 by removing the mask 520) is removed to expose the barrier layer 542. In some embodiments, removing the portion of the seed layer 518 to expose the barrier layer 542 comprises removing the portion of the seed layer 518 that is not covered by the copper features 526. In some embodiments, removing the portion of the seed layer comprises etching away the portion of the seed layer 518 by exposing the portion the seed layer 518 to an etchant. In some embodiments, etching away the portion the seed layer 518 comprises wet etching (e.g., blanket wet etching) or dry etching the portion of the seed layer 518. In some embodiments, exposing the portion of the seed layer 518 to the etchant results in a portion of the copper features 526 (e.g., a portion of the sidewalls 530 and/or the surface 528) being exposed to the etchant. In these embodiments, the etchant can also remove some of the copper metal from the copper features 526 during the etching process. Because the seed layer 518 is thin relative to the copper features 526, its removal does not significantly damage the copper features 526. In some embodiments, the etchant is configured to selectively etch copper without etching the conductive barrier material. In these embodiments, exposing the portion of seed layer 518 to the etchant can result in the barrier layer 542 not being etched (or not being significantly etched). In other embodiments, however, the etchant can slightly or completely etch the conductive barrier material. In such embodiments, exposing the seed layer 518 to the etchant can result in at least some of the barrier layer 542 also being removed by the etchant.

While FIGS. 5H and 5I show the result of a blanket etches, it will be understood that in other variants of all the embodiments herein, another mask may be provided to protect the copper features during removal of the seed and/or barrier layers. In such variants, the mask may be wider than the copper features to increase mask misalignment tolerance, and small wings or rings of the seed and/or barrier layers may remain extending a short distance from the base of the copper features over the first dielectric layer.

As shown in FIG. 5J, at block 420, to the extent not already removed by the prior seed layer removal, a portion of the barrier layer 542 (e.g., the portion exposed in the gaps 532 by removing the portion of the seed layer 518) is removed to expose the first dielectric layer 512. In some embodiments, removing the portion of the barrier layer 542 to expose the first dielectric layer 512 comprises removing the portion of the barrier layer 542 that is not covered by the copper features 526. In some embodiments, removing the portion of the barrier layer 542 comprises etching away the portion of the barrier layer 542 by exposing the portion of the barrier layer 542 to an etchant. In some embodiments, etching away the portion of the barrier layer 542 comprises wet etching (e.g., blanket wet etching) or dry etching the portion of the barrier layer 542. In some embodiments, exposing the portion of the barrier layer 542 to the etchant results in a portion the copper features 526 (e.g., a portion of the sidewalls 530 and/or the surface 528) being exposed to the etchant. In these embodiments, the etchant can also remove some of the copper metal from the copper features 526 during the etching process. In some embodiments, the etchant is configured to selectively the conductive barrier material without etching dielectric materials. In these embodiments, exposing the portion of the barrier layer 542 to the etchant can result in the surface 514 of the first dielectric layer 512 not being significantly etched. In other embodiments, however, the etchant can slightly etch dielectric materials. In these embodiments, exposing the barrier layer 542 to the etchant can result in at least some of the surface 514 also being removed by the etchant.

In the illustrated embodiments, the portion of the seed layer and the portion of the barrier layer are shown as being removed (e.g., etched away) in two distinct etching processes. In some embodiments, however, the portion of the seed layer and the portion of the barrier layer are removed in a single process (e.g., a single etching process). In these embodiments, the portion of the seed layer and the portion of the barrier layer are exposed to an etchant capable of etching both the copper metal of the seed layer and the conductive barrier material of the barrier layer.

As shown in FIG. 5K, at block 422, a second dielectric layer 534 is formed over the first dielectric layer 512 and the copper features 526. The second dielectric layer 534 is formed in the gaps 532 between the adjacent copper features 526 and, in some embodiments, completely fills the gaps 532. The second dielectric layer 534 directly contacts the sidewalls 530 of the copper features 526 and, in some embodiments, on the surfaces 528 of the copper features 526. While illustrated as a conformal deposition, as noted with respect to FIG. 3I, in other embodiments a self-leveling dielectric can be employed, such as spin-on glass (SOG). In some embodiments, the second dielectric layer 534 comprises an oxide material (e.g., an inorganic oxide material), such as a silicon oxide based material. For example, in some embodiments, the second dielectric layer 534 comprises silicon oxide (SiO₂), silicon oxynitride, silicon oxycarbide, or doped silicon oxide, such as F-doped SiO₂, borosilicate glass (BSG), or borophosphosilicate glass (BPSG). When the second dielectric layer 534 is formed over the copper features 526, the oxide material directly contacts the sidewalls 530 of the copper features 526 and can react with the copper metal that forms the sidewalls 530, resulting in the formation of copper oxide (e.g., Cu₂O, CuO) between the sidewalls 530 and the second dielectric layer 534. The presence of copper oxide on surfaces of the copper features 526 can even further lower adhesion between the copper features 526 and the second dielectric layer 534. Whether the surfaces are copper or copper oxide, the lack of an adhesion and/or barrier layer between the copper features 526 and the surrounding second dielectric layer 534 allows for a subsequent annealing step for hybrid bonding to be performed at a lower annealing temperature due to reduced friction during expansion. Forming the copper features 526 before depositing the second dielectric layer 534 between the already-formed copper features 526 (instead of depositing copper metal into patterned holes in the dielectric layer) can also leave a characteristic surface texture from exposure of the copper to a CVD oxide process, in contrast to damascene copper.

As shown in FIG. 5L, at block 424, the second dielectric layer 534 and the copper features 526 are planarized to form a bonding surface 536. In some embodiments, planarizing the second dielectric layer 534 comprises completely removing the portion of the second dielectric layer 534 formed above the copper features 526 to expose the copper features 526. In some embodiments, planarizing the second dielectric layer 534 also comprises removing a portion of the second dielectric layer 534 that is formed in the gaps 532. In some embodiments, planarizing the copper features 526 comprises removing at least some of the copper metal that forms the copper features 526.

The second dielectric layer 534 and the copper features 526 can be planarized using any suitable planarization process. As noted with respect to FIG. 3J, a CMP process can be performed with a single polishing pad and a single slurry chemistry, without the need to remove copper overburden as present in conventional damascene processing. For example, a “barrier slurry” can be used (although no barrier is being removed) because it polishes oxides and copper at roughly the same rate or can be tuned to slightly recess or slightly protrude the copper. After polishing, he top surface of the copper features 526 can be coplanar with, protrude slightly above, or recessed slightly below the top surface of the second dielectric layer 534, depending upon tuning and timing of the CMP process.

The bonding surface 536 comprises a hybrid bonding surface that includes a dielectric field region 538 and contact regions 540, where the dielectric field region 538 comprises the second dielectric layer 534 and the contact regions 540 are formed from the exposed surfaces of the copper features 526. In some embodiments, after planarizing the second dielectric layer 534 and the copper features 526, the contact regions 540 are flush with the dielectric field region 538. In other embodiments, however, the contact regions 540 are recessed below or slightly protruding above the dielectric field region 538.

The first dielectric layer 512, the second dielectric layer 534, copper features 526, and the conductive vias 516 define a bonding layer 548 of the element 500. The bonding layer 548 includes the bonding surface 536 and is formed on the surface 510 of the metallization layer 504. The bonding layer 548 includes a barrier layer 542 between the first dielectric layer 512 and the copper metal that fills the vias 516 but does not include a barrier layer between the copper features 526 and the second dielectric layer 534. Accordingly, the second dielectric layer 534, which can include silicon oxide, directly contacts the sidewalls 530 of the copper features 526, which can have copper or copper oxide surfaces.

At block 426, the bonding surface 536 is prepared for hybrid bonding. In some embodiments, preparing the bonding surface 536 for hybrid bonding comprises polishing the bonding surface 536. In some embodiments, preparing the bonding surface 536 comprises activating and/or terminating the bonding surface 536. In some embodiments, activating the bonding surface 536 comprises plasma activating the bonding surface 536 by exposing the bonding surface 536 to one or plasmas, such as a nitrogen plasma and/or an oxygen plasma. In some embodiments, activating the bonding surface 536 comprises chemically activating the bonding surface. In some embodiments, preparing the bonding surface 536 for hybrid bonding comprises rinsing the bonding surface 536 to remove any particulate matter on the bonding surface 536, and then drying the bonding surface 536. Activation and/or termination can sometimes be omitted, particularly if the other surface to be hybrid bonded to the bonding surface 536 is activated.

At block 428, a second element is provided. The second element comprises a bonding surface, a dielectric field region, and conductive features, where the bonding surface includes the conductive features and the dielectric field region. The bonding surface can be activated and prepared for hybrid bonding with element. In some embodiments, the second element can have a structure that is generally similar to the structure of element 500 in FIG. 5L, which can also be referred to as the first element 500, and/or similar to the second element 350 shown and described above in connection with FIG. 3L. In general, the second element can have any structure that is suitable for hybrid bonding with the element.

At block 430, the element 500 is hybrid bonded to the second element to form bonded structure. The element 500 is hybrid bonded to the second element without an intervening adhesive. As described above in connection with FIG. 3L, the element 500 can be hybrid bonded to the second element by contacting the bonding surface of the second element to the bonding surface 536 and then annealing the first element 500 and the second element. Annealing the element 500 and the second element causes the contact regions 540 to expand and contact the conductive features of the second element, which can cause the copper metal from the copper features 526 to inter-diffuse with the conductive metal of the conductive features. In some embodiments, due at least in part to the reduced adhesion between the copper features 526 and the second dielectric layer 534, annealing the first element 500 and the second element can be performed at a temperature of 250° C. or less.

After hybrid bonding the element 500 to the second element to form the bonded structure, the bonded structure can undergo additional processing, such as singulation, thinning, etching, depositing one or more additional layers over the backside of one or both of the elements, and/or bonding one or more other elements (e.g., dies, substrates, wafers, etc.) to the backside (e.g., to the bonding surface or the conductive layer) of one or both of the elements.

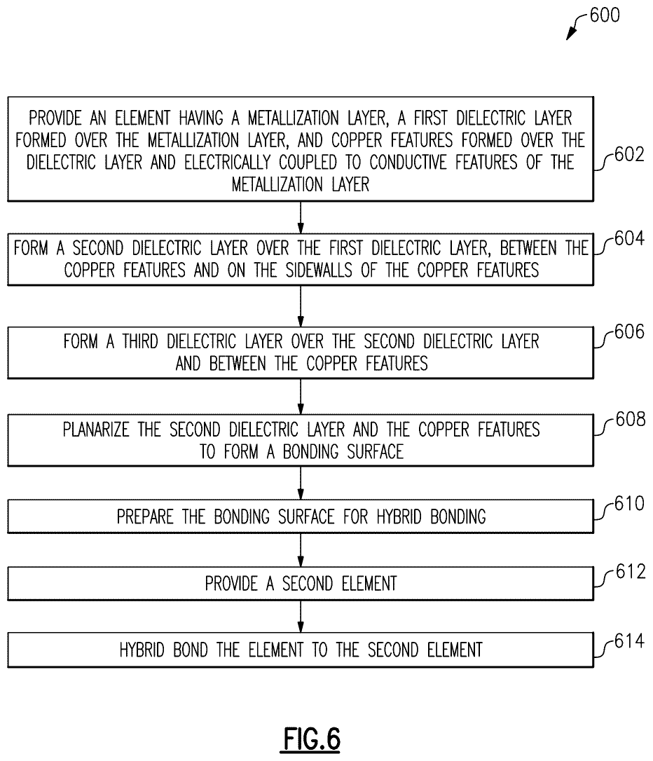

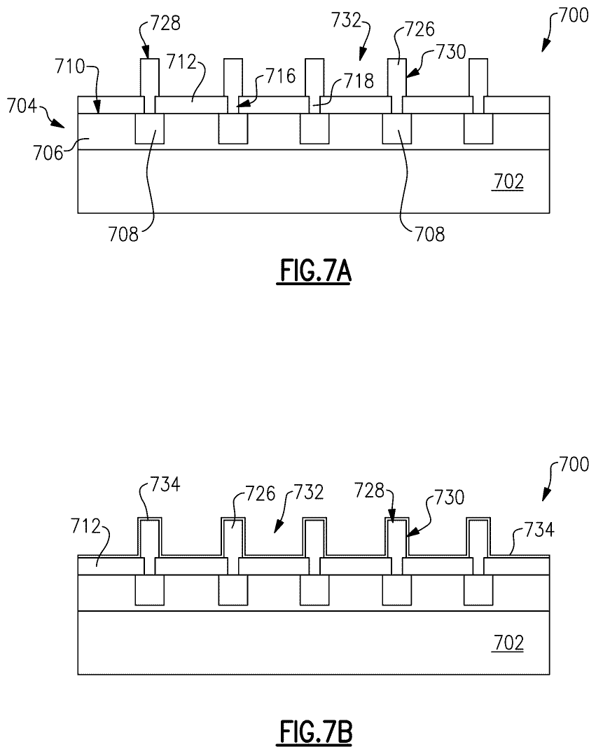

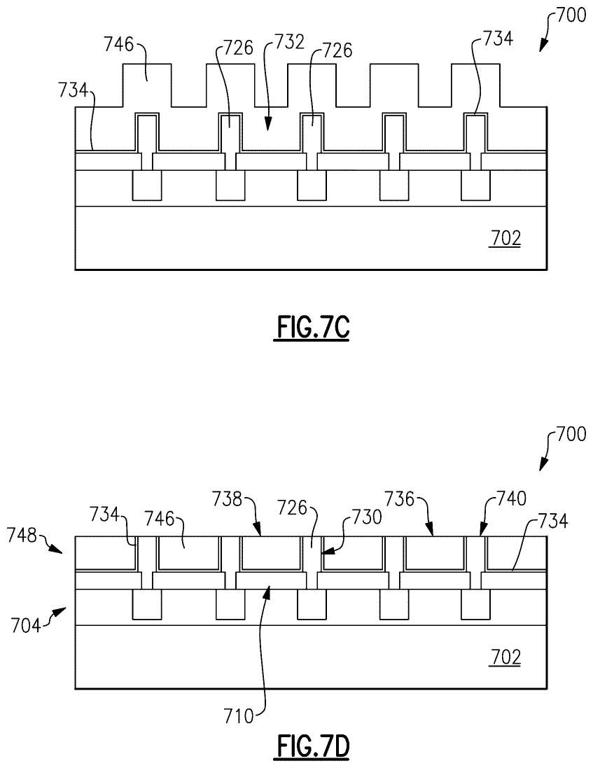

In the embodiments illustrated in FIGS. 2-5L, a single dielectric layer is formed in the gaps between the copper features (e.g., the gaps 332, 532 between copper features 326, 526). In other embodiments, however, multiple dielectric layers can be formed in the gaps between the copper features. FIG. 6 is a flowchart illustrating a process 600 for forming a microelectronic component that includes forming a bonding layer on an element, where the bonding layer includes multiple dielectric layers formed in the gaps between adjacent copper features. FIGS. 7A-7D are schematic side sectional views of microelectronic elements at various blocks of the process 600 shown in FIG. 6.

As shown in FIG. 7A, at block 602, a microelectronic element 700 is provided. The element 700 comprises a base substrate portion 702 and a metallization layer 704 formed over the base substrate portion 702. The metallization layer 704 includes a field dielectric 706 and conductive features 708 formed in the field dielectric 706. A first dielectric layer 712 is formed on a surface 710 of the metallization layer and the first dielectric layer 712 has vias 716 formed in it. A seed layer 718 is formed in the vias 716 and copper features 726 are formed over the seed layer 718. The copper features 726 have an upper surface 728 and sidewalls 730 and adjacent copper features 726 are separated from each other by gaps 732. In the illustrated embodiment, the element 700 does not include a barrier layer between the first dielectric layer 712 and the seed layer 718 and is therefore generally similar to the element 300 shown in FIG. 3H. Accordingly, the element 700 can be formed according to blocks 202-216 of process 200. In other embodiments, however, the element 700 can include a barrier layer between the first dielectric layer 712 and the seed layer 718 and can therefore be generally similar to element 500 shown in FIG. 5J. In these embodiments, the element 700 can be formed according to blocks 402-420. In some variants, another mask is used to protect the copper features 726 during removal of the seed and/or barrier layers, leaving short wings or rings of the seed and/or barrier layers extending from the base of the copper features over the first dielectric layer 712.

As shown in FIG. 7B, at block 804, a second dielectric layer 734 is formed over the first dielectric layer 712 and the copper features 726. The second dielectric layer 734 is formed conformally in the gaps 732 between the adjacent copper features 726 but does not completely fill the gaps 732. In some embodiments, the second dielectric layer 734 can have a thickness of about 10 nm to about 100 nm. The second dielectric layer 734 directly contacts the sidewalls 730 of the copper features 726 and, in some embodiments, on the upper surfaces 728 of the copper features 726. In some embodiments, the second dielectric layer 734 comprises an oxide material (e.g., an inorganic oxide material), such as silicon oxide based material. For example, in some embodiments the second dielectric layer 734 comprises silicon oxide, silicon oxynitride, silicon oxycarbide, or doped silicon oxide (SiO₂), such as F-doped SiO₂, borosilicate glass (BSG), or borophosphosilicate glass (BPSG). When the second dielectric layer 734 is formed over the copper features 726, the oxide material directly contacts the sidewalls 730 of the copper features 726 and can react with the copper metal that forms the sidewalls 730, resulting in the formation of copper oxide (e.g., Cu₂O, CuO) between the sidewalls 730 and the second dielectric layer 734. Any copper oxide formed on sidewalls of the copper features 726 can even further lower adhesion between the copper features 726 and the second dielectric layer 734, which allow for a subsequent annealing step to be performed at a lower annealing temperature. Forming the copper features 726 before depositing the second dielectric layer 734 between the already-formed copper features 526 (in contrast to damascene patterning) can also leave a characteristic surface from exposure of the copper to a CVD oxide process, in contrast to damascene copper.

As shown in FIG. 7C, at block 606, a third dielectric layer 746 is formed over the second dielectric layer 734. The third dielectric layer 746 is formed in the gaps 732 between the adjacent copper features 726 and, in combination with the second dielectric layer 734, completely fills the gaps 732. The third dielectric layer 746 can be formed directly on the second dielectric layer 734 and therefore does not directly contact the copper features 726. In some embodiments, the third dielectric layer 746 comprises an inorganic dielectric material. In some embodiments, the third dielectric layer 746 comprises the same dielectric material that the second dielectric layer 734 is formed from (e.g., silicon oxide). In other embodiments, however, the third dielectric layer 746 comprises a different dielectric material. For example, in some embodiments, the third dielectric layer comprises silicon nitride. In other embodiments, however, the third dielectric layer 746 comprises a different inorganic dielectric material, such as silicon oxynitride, silicon carbide, silicon oxycarbonitride, low K dielectric materials, SiCOH dielectrics, silicon carbonitride, diamond-like carbon, a material comprising a diamond surface, or combinations thereof. In general, the third dielectric layer 746 can be formed from any dielectric material capable of forming a dielectric-to-dielectric direct bond with another dielectric material.

In the illustrated embodiment, the second dielectric layer 734 comprises an inorganic oxide material (e.g., silicon oxide) and the third dielectric layer 746 can comprise a different dielectric material which need not be an oxide, such as silicon nitride or silicon carbide. In other embodiments, however, the third dielectric layer 746 comprises an oxide material and the second dielectric layer 734 comprises the different dielectric material which need not be an oxide.

As shown in FIG. 7D, at block 608, the second dielectric layer 734, the third dielectric layer 746, and the copper features 726 are planarized to form a bonding surface 736. In some embodiments, planarizing the second dielectric layer 734 and the third dielectric layer 746 comprises completely removing the portions of the second dielectric layer 734 and the third dielectric layer 746 that are formed over the copper features 726 to expose the copper features 726. In some embodiments, planarizing the second dielectric layer 734 and the third dielectric layer 746 also comprises removing some of the portions of the second dielectric layer 334 and third dielectric layer 746 that are formed in the gaps 732. In some embodiments, planarizing the copper features 726 comprises removing at least some of the copper metal that forms the copper features 726.

The second dielectric layer 734, the third dielectric 746, and the copper features 726 can be planarized using any suitable planarization process. For example, in some embodiments, the planarization process comprises a CMP process that involves using a polishing pad and a slurry to polish the second dielectric layer 734, the third dielectric layer 746, and the copper features 726 to form the bonding surface 736. As noted above with respect to FIG. 3I, the CMP process can be performed with a single polishing pad and a single slurry chemistry, without the need to remove copper overburden as present in conventional damascene processing. For example, a “barrier slurry” can be used (although no barrier is being removed) because it polishes oxides and copper at roughly the same rate or can be tuned to slightly recess or slightly protrude the copper. After performing the polishing process, the top surface of the copper features 726 can be coplanar with, protrude slightly above, or be recessed slightly below the top surface of the second dielectric layer 734 and the third dielectric layer 746, depending upon tuning and timing of the CMP process.

The bonding surface 736 comprises a hybrid bonding surface that includes a dielectric field region 738 and contact regions 740, where the dielectric field region 738 comprises the second dielectric layer 734 and the third dielectric layer 746 and the contact regions 740 are formed from the exposed surfaces of the copper features 726. In some embodiments, after planarizing the second dielectric layer 734, the third dielectric layer 746, and the copper features 726, the contact regions 740 are flush with the dielectric field region 738. In other embodiments, however, the contact regions 740 are recessed below the dielectric field region 738.

The first dielectric layer 712, the second dielectric layer 734, the third dielectric layer 746, the copper features 726, and the conductive vias 716 define a bonding layer 748 of the element 700. The bonding layer 748 includes the bonding surface 736 and is formed on the surface 710 of the metallization layer 704. However, the bonding layer 748 does not include a barrier layer between the copper features 726 and the second dielectric layer 734. Accordingly, the second dielectric layer 734, which can include silicon oxide, directly contacts the sidewalls 730 of the copper features 726, which can result in copper oxide forming on the sidewalls 730 of the copper features 726.

At block 610, the bonding surface 736 is prepared for hybrid bonding. In some embodiments, preparing the bonding surface 736 for hybrid bonding comprises polishing the bonding surface 736. In some embodiments, preparing the bonding surface 736 comprises activating and/or terminating the bonding surface 736 for direct bonding. In some embodiments, activating the bonding surface 736 comprises plasma activating the bonding surface 736 by exposing the bonding surface 736 to one or plasmas, such as a nitrogen plasma and/or an oxygen plasma. In some embodiments, activating the bonding surface 736 comprises chemically activating the bonding surface. In some embodiments, preparing the bonding surface 736 for hybrid bonding comprises rinsing the bonding surface 736 to remove any particulate matter on the bonding surface 736, and then drying the bonding surface 736. Activation and/or termination can sometimes be omitted, particularly if the other surface to be hybrid bonded to the bonding surface 736 is activated.

At block 612, a second element is provided. The second comprises a bonding surface that includes a dielectric field region and conductive features. The bonding surface can be activated and prepared for hybrid bonding with element 700. In some embodiments, the second element can have a structure that is generally similar to the structure of element 700, which can also be referred to as the first element 700, and/or to the second element 350 shown and described above in connection with FIG. 3K. In general, the second element can have any structure that is suitable for hybrid bonding with the element 700.

At block 614, the element 700 is hybrid bonded to the second element to form bonded structure. The element 700 is hybrid bonded to the second element without an intervening adhesive. The element 700 can be hybrid bonded to the second element by contacting the bonding surface of the second element to the bonding surface 736 and then annealing the element 700 and the second element. Annealing the element 700 and the second element causes the contact regions 740 of the element 700 to expand and contact the conductive features of the second element, which can cause the copper metal from the copper features 726 to inter-diffuse with the conductive metal of the conductive features. In some embodiments, due at least in part to the reduced adhesion between the copper features 726 and the second dielectric layer 734, annealing the first element 700 and the second element can be performed at a temperature of 250° C. or less.

After hybrid bonding the element 700 to the second element to form the bonded structure, the bonded structure can undergo additional processing, such as singulation, thinning, etching, depositing one or more additional layers over the backside of the element 700 and/or the second element, and/or bonding one or more other elements (e.g., dies, substrates, wafers, etc.) to the backside (e.g., to the bonding surface or the conductive layer) of one or both of the elements.

In the embodiments illustrated in FIGS. 2-7D, the bonding layers 348, 548, 748 are formed by forming an initial dielectric layer (e.g., first dielectric layers 312, 512, 712) on the metallization layer before the copper features (e.g., copper features 326, 526, 726) and oxide-containing dielectric layers (e.g., second dielectric layers 334, 534, 734) are formed, resulting in the bonding layers having multiple dielectric layers formed over the metallization layer and a dielectric layer between the copper features and the metallization layer. In other embodiments, however, the initial dielectric layer can be omitted and the copper features are formed directly over the metallization layer. FIG. 8 is a flowchart illustrating a process 800 for forming a microelectronic component that includes forming a bonding layer on an element, where the bonding layer does not include a dielectric material between bonding layer and the metallization layer. FIGS. 9A-9H are schematic side sectional views of microelectronic elements at various blocks of the process 800 shown in FIG. 8.

As shown in FIG. 9A, at block 802, a microelectronic element 900 is provided. The element 900, which can be generally similar to the elements 300, 500, 700 shown and described in connection with FIG. 3A, 5A, 7A, comprises a base substrate portion 902 and a metallization layer 904 formed over the base substrate portion 902. The metallization layer 904 includes a field dielectric 906 and conductive features 908 formed in the field dielectric 906. The metallization layer 904 has a surface 910 that is defined by the field dielectric 906 and the conductive features 908. In some embodiments, the field dielectric 906 comprises an inorganic dielectric, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. In some embodiments, the conductive features 908 comprise a conductive metal, such as copper, aluminum, or alloys thereof. In some embodiments, the metallization layer 904 is formed at a back side of the element 900. In other embodiments, the metallization layer 904 is formed at a front side of the element 900 closest to active devices of the element 900. The illustrated metallization layer 904 can be the uppermost or last metallization layer of a plurality of BEOL metallization layers on a particular side of a microelectronic element. Accordingly, the metallization layer 904 can be formed at a chip foundry, for example, using process nodes typical for BEOL at the foundry, as opposed to a packaging facility.

As shown in FIG. 9B, at block 804, a seed layer 918 is formed over the surface 910 of the metallization layer 904. In the illustrated embodiment, the seed layer 918 completely covers the surface 910, including the field dielectric 906 and the conductive features 908. In other embodiments, the seed layer 918 completely covers the conductive features 908 but may only partially cover the field dielectric 906 or may not cover the field dielectric 906. The seed layer 918 comprises a conductive metal such as copper metal or aluminum metal. In some embodiments, the seed layer 918 comprises the same conductive metal as the conductive metal from which the conductive features 908 are formed. In other embodiments, the seed layer 918 comprises a different conductive metal than the conductive metal from which the conductive features 908 are formed.

In some embodiments, including the embodiment illustrated in FIG. 9B, the seed layer 918 is formed directly on the surface 910. In other embodiments, however, a barrier layer can be formed on the surface 910 before the seed layer 918 is formed (see FIGS. 4-5L and attendant description). In these embodiments, the barrier layer, which can comprise a conductive barrier material, is formed directly on the surface 910 such that it at least partially covers the surface 910. After forming the barrier layer, the seed layer 918 can then be formed on the barrier layer.

As shown in FIG. 9C, at block 806, a mask 920 is formed over the seed layer 918 and patterned to form openings 922 in the mask 920. The mask 920 can be formed, for example, from any suitable resist material and can be patterned using any suitable patterning technique, such as irradiation and development, or by etching from a resist mask into a hard mask material. The openings 922 can extend through the mask 920 and can be formed over the conductive features 908 such that the portions of the seed layer 918 formed over the conductive features 908 are exposed through the openings 922. In the illustrated embodiment, the openings 922 are narrower than the conductive features 908. The openings 922 have sidewalls 924 and can have a straight profile, a reentrant profile, or any other suitable profile and, in some embodiments, the profile can be can depend on the process used to pattern the openings 922 in the mask 920 and/or the material from which the mask 920 is formed. For example, in some embodiments the sidewalls 924 of the mask 920 can have an undulating shape due to standing waves during exposure of photoresist for patterning

As shown in FIG. 9D, at block 808, copper features 926 are formed in the openings 922. The copper features 926 directly contact the seed layer 918 and have sidewalls 930 that contact the sidewalls 924 of the mask 920. In some embodiments, the copper features 926 completely cover the portions of the seed layer 918 formed over the conductive features 908. In some embodiments, the copper features 926 are formed in the openings 922 by plating (e.g., electroplating) copper metal into the openings 922. In some embodiments, the copper features 926 completely fill the openings 922 such that a surface 928 of the copper features 926 is generally coplanar with the top surface of the mask 920. In other embodiments, however, the copper features 926 do not completely fill the openings 922 such that the surface 928 is recessed below the top surface of the mask 920. The copper features 926 can have a straight profile, a reentrant profile, or any other suitable profile. In some embodiments sidewalls of the copper features 926 can demonstrate an undulating surface characteristic of standing waves during exposure of photoresist for patterning. In general, the copper features 926 can have any suitable shape.

As shown in FIG. 9E, at block 810, the mask 920 is removed to expose a portion of the seed layer 918 and to expose the sidewalls 930 of the copper features 926. After removing the mask 920, the copper features 926 can be separated from each other by gaps 932, which can extend between adjacent copper features 926. The mask 920 can be stripped using any suitable selective removal process, such as resist stripping.

As shown in FIG. 9F, at block 812, the portions of the seed layer 918 that are exposed in the gaps 932 between the copper features 926 are removed. In some embodiments, including the illustrated embodiment, the seed layer 918 is formed directly on the surface 910 of the metallization layer 904. In these embodiments, removing the portions of the seed layer 918 that are exposed in the gaps 932 between the copper features 926 results in the surface 910 being exposed. In some embodiments, removing the portions of the seed layer 918 that are exposed in the gaps 932 between the copper features comprises removing the portions of the seed layer 918 that are not covered by the copper features 926. Accordingly, after removing the portion of the seed layer 918, portions of the seed layer 918 remain below the copper features 926. In some embodiments, removing the portion of the seed layer comprises etching away the portion of the seed layer 918 by exposing the portion the seed layer 918 to an etchant. In some embodiments, etching away the portion the seed layer 918 comprises wet etching (e.g., blanket wet etching) or dry etching the portion of the seed layer 918. In some embodiments, exposing the portion of the seed layer 918 to the etchant results in a portion of the copper features 926 (e.g., a portion of the sidewalls 930 and/or the surface 928) being exposed to the etchant. In these embodiments, the etchant can also remove some of the copper metal from the copper features 926 during the etching process, but because the seek layer 918 is thin, very little of the copper features 926 is removed.

In embodiments where the barrier layer is formed directly on the surface 910 and the seed layer 918 is formed on the barrier layer, removing the portion of the seed layer 918 that is exposed in the gaps 932 between the copper features 926 results in a portion of the barrier layer being exposed. In some embodiments, the etchant is configured to selectively etch copper without etching the conductive barrier material. In these embodiments, exposing the portion of seed layer 918 to the etchant can result in the barrier layer 942 not being etched (or not being significantly etched). In other embodiments, however, the etchant can slightly etch the conductive barrier material. In these embodiments, exposing the seed layer 918 to the etchant can result in at least some of the barrier layer 942 also being removed by the etchant. Additionally, the process 800 can also include removing portions of the barrier layer (e.g., the portions exposed in the gaps 932 by removing the portions of the seed layer 918) to expose the surface 910 of the metallization layer 904. In some embodiments, removing the portions of the barrier layer that are exposed in the gaps 932 between the copper features comprises removing the portions of the barrier layer that are not covered by the copper features 926. Accordingly, after removing the portion of the barrier layer, the portions of the barrier layer over which the copper features 926 are formed (e.g., the portions of the barrier between the copper features 926 and the conductive features 908) can still be present. In some embodiments, removing the portion of the barrier layer comprises etching away the portion of the barrier layer by exposing the portion of the barrier layer to an etchant. As noted previously, the removal of the seed layer 918 and any underlying barrier layer can employ another mask to protect the copper features 926, in which case short wings or rings of seed and/or barrier material can remain extending from the base of the copper features 926 over the metallization layer 904.

As shown in FIG. 9G, at block 814, a dielectric layer 934 is formed over the field dielectric 906 and the copper features 926. The dielectric layer 934 is formed in the gaps 932 between the adjacent copper features 926 and, in some embodiments, completely fills the gaps 932. While illustrated as a conformal deposition, such as by chemical vapor deposition (CVD), in which significant undulations are left by the dielectric layer 334 overlying the copper features 326, the skilled artisan will understand that in other embodiments a self-leveling dielectric can be employed, such as spin-on glass (SOG). The dielectric layer 934 directly contacts the sidewalls 930 of the copper features 926 and, in some embodiments, on the surfaces 928 of the copper features 926. In some embodiments, the dielectric layer 934 comprises an oxide material (e.g., an inorganic oxide material), such as a silicon oxide based material. For example, in some embodiments, the second dielectric layer 934 comprises silicon oxide (SiO₂), silicon oxynitride, silicon oxycarbide, or doped silicon oxide, such as F-doped SiO₂, borosilicate glass (BSG), or borophosphosilicate glass (BPSG). When the dielectric layer 934 is formed over the copper features 926, the oxide material directly contacts the sidewalls 930 of the copper features 926 and can react with the copper metal that forms the sidewalls 930, resulting in the formation of copper oxide (e.g., Cu₂O, CuO) between the sidewalls 930 and the dielectric layer 934. The presence of copper oxide between the copper of the copper features 926 and the dielectric layer 934 can even further lower adhesion between the copper features 926 and the dielectric layer 934, which allow for a subsequent annealing step to be performed at a lower annealing temperature. Forming the copper features 926 before depositing the dielectric layer 934 between the already-formed copper features 926 (instead of depositing copper metal into patterned holes in the dielectric layer) can also leave a characteristic surface from exposure of the copper to a CVD oxide process, in contrast to damascene copper.

As shown in FIG. 9H, at block 816, the dielectric layer 934 and the copper features 926 are planarized to form a bonding surface 936. The dielectric layer 934 and the copper features 926 can be planarized using any suitable planarization process. In some embodiments, planarizing the dielectric layer 934 comprises completely removing the portion of the dielectric layer 934 formed above the copper features 926 to expose the copper features 926. In some embodiments, planarizing the dielectric layer 934 also comprises removing the portion of the dielectric layer 934 formed in the gaps 932. In some embodiments, planarizing the copper features 926 comprises removing at least some of the copper metal that forms the copper features 926.

The second dielectric layer 934 and the copper features 926 can be planarized using any suitable planarization process. For example, in some embodiments, the planarization process comprises a CMP process that involves using a polishing pad and a slurry to polish the second dielectric layer 934 and the copper features 926 to form the bonding surface 936. Additionally, unlike in conventional damascene processes where a significant copper overburden is to be removed, the CMP process can be performed with a single polishing pad and a single slurry chemistry, without the need to remove copper overburden as present in conventional damascene processing. For example, a “barrier slurry” can be used (although no barrier is being removed) because it polishes oxides and copper at roughly the same rate or can be tuned to slightly recess or slightly protrude the copper. After performing the polishing process using the single polishing pad and the single slurry chemistry, the top surface of the copper features 926 can be coplanar with, protrude slightly above, or be recessed below the top surface of the second dielectric layer 934, depending upon tuning and timing of the CMP process.

The bonding surface 936 comprises a hybrid bonding surface that includes a dielectric field region 938 and contact regions 940, where the dielectric field region 938 comprises the dielectric layer 934 and the contact regions 940 are formed from the exposed surfaces of the copper features 926. In some embodiments, after planarizing the dielectric layer 934 and the copper features 926, the contact regions 940 are flush with the dielectric field region 938. In other embodiments, however, the contact regions 940 are recessed below the dielectric field region 938.

The dielectric layer 934 and copper features 926 define a bonding layer 948 of the element 900. The bonding layer 948 includes the bonding surface 936 and is formed on the surface 910 of the metallization layer 904. In some embodiments, including the illustrated embodiment, the bonding layer 948 does not include a barrier layer (e.g., no barrier layer between the copper features 926 and the conductive features 908). In other embodiments, however, the bonding layer 948 includes a barrier layer between the copper features 926 and the conductive features 908. The dielectric layer 934, which can include silicon oxide, directly contacts the sidewalls 930 of the copper features 926, which can result in the formation of copper oxide forming on the sidewalls 930 of the copper features 926. The dielectric layer 934 also directly contacts the field dielectric 906 of the metallization layer 904.

At block 818, the bonding surface 936 is prepared for hybrid bonding. In some embodiments, preparing the bonding surface 936 for hybrid bonding comprises polishing the bonding surface 936. In some embodiments, preparing the bonding surface 936 comprises activating and/or terminating the bonding surface 936. In some embodiments, activating the bonding surface 936 comprises plasma activating the bonding surface 936 by exposing the bonding surface 936 to one or plasmas, such as a nitrogen plasma and/or an oxygen plasma. In some embodiments, activating the bonding surface 936 comprises chemically activating the bonding surface. In some embodiments, preparing the bonding surface 936 for hybrid bonding comprises rinsing the bonding surface 936 to remove any particulate matter on the bonding surface 936, and then drying the bonding surface 936. Activation and/or termination can sometimes be omitted, particularly if the other surface to be hybrid bonded to the bonding surface 536 is activated.

At block 820, a second element is provided. The second comprises a bonding surface that includes a dielectric field region and conductive features. The bonding surface can be activated and prepared for hybrid bonding with element 900. In some embodiments, the second element can have a structure that is generally similar to the structure of element 900, which can also be referred to as the first element 900, and/or to the second element 350 shown and described above in connection with FIG. 3K. In general, the second element can have any structure that is suitable for hybrid bonding with the element 900.

At block 822, the element 900 is hybrid bonded to the second element to form bonded structure. The element 900 is hybrid bonded to the second element without an intervening adhesive. The element 900 can be hybrid bonded to the second element by contacting the bonding surface of the second element to the bonding surface 936 and then annealing the element 900 and the second element. Annealing the element 900 and the second element causes the contact regions 940 of the element 900 to expand and contact the conductive features of the second element, which can cause the copper metal from the copper features 926 to inter-diffuse with the conductive metal of the conductive features. In some embodiments, due at least in part to the reduced adhesion between the copper features 926 and the dielectric layer 934, annealing the first element 900 and the second element can be performed at a temperature of 250° C. or less.

After hybrid bonding the element 900 to the second element to form the bonded structure, the bonded structure can undergo additional processing, such as singulation, thinning, etching, having one or more additional layers deposited over the backside of the element 900 and/or the second element, and/or having one or more other elements (e.g., dies, substrates, wafers, etc.) be bonded to the backside (e.g., to the bonding surface or the conductive layer) of one or both of the elements.

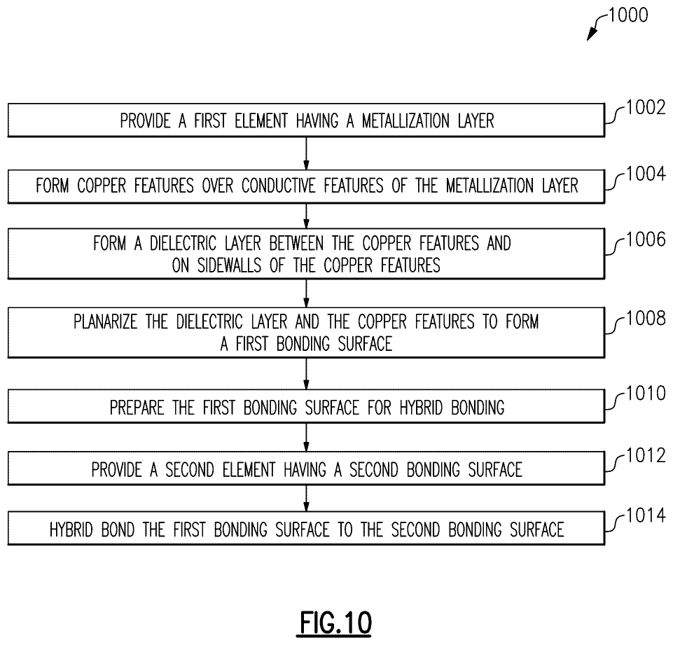

FIG. 10 is a flowchart illustrating a process 1000 for forming a microelectronic component that includes forming a bonding layer on an element, where the bonding layer includes copper features and a dielectric layer that directly contacts the sidewalls of the copper features, with or without oxidation of the copper surfaces.

At block 1002, a first element having a metallization layer is provided. The first element, which can be generally similar to the elements 300, 500, 700, 900 shown and described in connection with FIGS. 3A, 5A, 7A, 9A, comprises a base substrate portion and a metallization layer formed over the base substrate portion. The metallization layer includes a field dielectric and conductive features formed in the field dielectric. The metallization layer has a surface that is defined by the field dielectric and the conductive features. In some embodiments, the field dielectric 906 comprises an inorganic dielectric, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. In some embodiments, the conductive features comprise a conductive metal, such as copper, aluminum, or alloys thereof. In some embodiments, the metallization layer is formed at a back side of the element. In other embodiments, the metallization layer is formed at a front side of the element. The illustrated metallization layer can be the uppermost or last metallization layer of a plurality of BEOL metallization layers on a particular side of a microelectronic element. Accordingly, the metallization layer can be formed at a chip foundry, for example, using process nodes typical for BEOL at the foundry, as opposed to a packaging facility.

At block 1004, copper features are formed over the conductive features of the metallization layer. The copper features comprise copper metal and are formed such that they extend away from the metallization layer and such that adjacent copper features are spaced apart from each other by gaps. In some embodiments, the copper features include a barrier layer formed around a bottom portion of the copper features without extending over sidewalls of the copper features. In other embodiments, the copper features do not include a barrier layer.

The copper features can be formed using any suitable process. For example, in some embodiments the copper features are formed by depositing a dielectric layer over surface of the metallization layer, forming vias in the dielectric layer, depositing a seed layer over the dielectric layer and into the vias, forming and patterning a mask to form openings in the mask over the vias, depositing copper metal into the openings over the seed layer, removing the mask to expose the seed layer, and then removing the exposed portion of the seed layer to expose the dielectric layer. In some embodiments, the copper features are formed by depositing a dielectric layer over surface of the metallization layer, forming vias in the dielectric layer, depositing a barrier layer over the dielectric layer and into the vias, depositing a seed layer over the barrier layer and into the vias, forming and patterning a mask to form openings in the mask over the vias, depositing copper metal into the openings over the seed layer, removing the mask to expose the seed layer, removing the exposed portion of the seed layer to expose the barrier layer, and then removing the exposed portion of the barrier layer to expose the dielectric layer. In some embodiments, the copper features are formed by depositing a seed layer over the metallization layer, forming and patterning a mask to form openings in the mask over the conductive features of the metallization layer, depositing copper metal into the openings over the seed layer, removing to expose the seed layer, removing the exposed portion of the seed layer (and optionally removing an exposed portion of the barrier layer) to expose the field dielectric of the metallization layer. A barrier layer can also underlie the seed layer in some embodiments.

At block 1006, after forming the copper features, a dielectric layer is formed between the copper features and on the sidewalls of the copper features. The dielectric layer is formed in the gaps between the adjacent copper features and completely fills the gaps. The dielectric layer directly contacts the sidewalls of the copper features and, in some embodiments, is formed on the upper surfaces of the copper features. In some embodiments, the dielectric layer comprises a single dielectric material. In other embodiments, the dielectric layer comprises multiple dielectric materials layered together. The dielectric layer comprises an oxide material (e.g., an inorganic oxide material), such as silicon oxide (SiO₂). In embodiments where the dielectric layer comprises multiple dielectric materials layered together, the portion of the dielectric layer that contacts the sidewalls of the copper features comprises the silicon oxide. When the dielectric layer is formed over the copper features, the oxide material directly contacts the sidewalls of the copper features and can react with the copper metal that forms the sidewalls, resulting in the formation of copper oxide (e.g., Cu₂O, CuO) on the copper sidewalls. The presence of copper oxide between the copper of the copper features and the second dielectric layer results in an even lower adhesion between the copper features and the second dielectric layer, which allows for a subsequent annealing step to be performed at a lower annealing temperature. Forming the copper features before depositing the second dielectric layer between the already-formed copper features (instead of depositing copper metal into patterned holes in the dielectric layer) avoids the need to remove a large copper overburden, as compared to damascene processing.

At block 1008, the dielectric layer and the copper features are planarized to form a bonding surface. The dielectric layer and the copper features can be planarized using any suitable planarization process. In some embodiments, planarizing the dielectric layer comprises completely removing the portion of the dielectric layer formed above the copper features to expose the copper features. In some embodiments, planarizing the dielectric layer also comprises removing the portion of the dielectric layer formed in the gaps between the copper features. In some embodiments, planarizing the copper features comprises removing at least some of the copper metal that forms the copper features.

The dielectric layer and the copper features can be planarized using any suitable planarization process. For example, in some embodiments, the planarization process comprises a CMP process that involves using a polishing pad and a slurry to polish the dielectric layer and the copper features to form the bonding surface. Additionally, unlike in conventional damascene processes where a large copper overburden is removed, the CMP process can be performed with a single polishing pad and a single slurry chemistry. After performing the CMP process using the single polishing pad and the single slurry chemistry, the top surface of the copper features can be coplanar with, protrude slightly above, or be recessed slightly below the top surface of the second dielectric layer.

The bonding surface comprises a hybrid bonding surface that includes a dielectric field region and contact regions, where the dielectric field region comprises the dielectric material of the dielectric layer formed between the copper features and the contact regions are formed from the exposed surfaces of the copper features. In some embodiments, after planarizing the dielectric layer and the copper features, the contact regions are flush with the dielectric field region. In other embodiments, however, the contact regions are recessed below the dielectric field region.

The dielectric layer and the copper features define a bonding layer of the element. The bonding layer includes the bonding surface is formed on the surface of the metallization layer of the element. The bonding layer does not include a barrier layer between the copper features and the dielectric layer. Accordingly, the dielectric layer, which can include silicon oxide, directly contacts the sidewalls of the copper features, which can result in the formation of copper oxide forming on the sidewalls of the copper features.

At block 1010, the bonding surface of the bonding layer is prepared for hybrid bonding. In some embodiments, preparing the bonding surface for hybrid bonding comprises polishing the bonding surface. In some embodiments, preparing the bonding surface further comprises activating and/or terminating the bonding surface. In some embodiments, activating the bonding surface comprises plasma activating the bonding surface by exposing the bonding surface to one or plasmas, such as a nitrogen plasma and/or an oxygen plasma. In some embodiments, activating the bonding surface comprises chemically activating the bonding surface. In some embodiments, preparing the bonding surface for hybrid bonding comprises rinsing the bonding surface to remove any particulate matter on the bonding surface, and then drying the bonding surface. Activation and/or termination can sometimes be omitted, particularly if the other surface to be hybrid bonded to the bonding surface is activated.

At block 1012, a second element is provided. The second comprises a bonding surface that includes a dielectric field region and conductive features. The bonding surface can be prepared for hybrid bonding (e.g., polished, activated and/or terminated) with the first element. In some embodiments, the second element can have a structure that is generally similar to the structure of the first element, and/or to the second element 350 shown and described above in connection with FIG. 3K. In general, the second element can have any structure that is suitable for hybrid bonding with the element.

At block 1014, the first element is hybrid bonded to the second element to form bonded structure. The first element is hybrid bonded to the second element without an intervening adhesive. The first element can be hybrid bonded to the second element by contacting the bonding surface of the second element to the bonding surface of the first element and then annealing the first and second elements. Annealing the first and second elements causes the contact regions of the first element to expand and contact the conductive features of the second element, which can cause the copper metal from the copper features to inter-diffuse with the conductive metal of the conductive features. In some embodiments, due at least in part to the reduced adhesion between the copper features and the dielectric layer, annealing the first element and the second element can be performed at a temperature of 250° C. or less.

After hybrid bonding the first element to the second element to form the bonded structure, the bonded structure can undergo additional processing, such as singulation, thinning, etching, having one or more additional layers deposited over the backside of the first element and/or the second element, and/or having one or more other elements (e.g., dies, substrates, wafers, etc.) be bonded to the backside (e.g., to the bonding surface or the conductive layer) of one or both of the elements.

### Additional Examples

Accordingly to one aspect, a method is provided for forming a microelectronic element. The method includes providing an element having a metallization layer that includes a field dielectric and a conductive feature embedded in the field dielectric. The method also includes forming a copper feature over the conductive feature. After forming the copper feature, a dielectric layer is formed over sidewalls of the copper feature. The dielectric layer is planarized to form a hybrid bonding surface, where the copper feature is exposed at the hybrid bonding surface.

In some embodiments, the dielectric layer includes silicon oxide. The dielectric layer can be formed over the sidewalls of the copper feature such that the silicon oxide directly contacts the sidewalls of the copper feature.

In some embodiments, the dielectric layer includes a first dielectric layer, and the method also includes, before forming the copper feature over the conductive feature, forming a second dielectric layer over the metallization layer. A via is formed in the second dielectric layer to expose a portion of the conductive feature through the second dielectric layer. After forming the copper feature over the conductive feature, at least a portion of the copper feature is within the via. In some embodiments, the method can also include, after forming the second dielectric layer over the metallization layer but before forming the copper feature over the conductive feature, forming a barrier layer over the second dielectric layer and the portion of the conductive feature. In some embodiments, after forming the copper feature over the conductive feature, a portion of the barrier layer is removed to expose the second dielectric layer. The barrier layer can cover the first dielectric layer. In some embodiments, the portion of the barrier layer includes a first portion, and the barrier layer includes comprises a second portion, where the first portion is formed over the first dielectric layer and the second portion is formed over the conductive feature. In some embodiments, the second portion is formed over the portion of the conductive feature. In some embodiments, forming the copper feature over the conductive feature includes forming the copper feature over the second portion of the barrier layer. In some embodiments, removing the portion of the barrier layer to expose the second dielectric layer includes etching the barrier layer to completely remove the portion of the barrier layer. In some embodiments, the barrier layer is not formed on the sidewalls of the copper feature. In some embodiments, the barrier layer includes titanium. In some embodiments, the barrier layer includes tantalum.

In some embodiments, forming the copper feature over the conductive feature includes forming a seed layer over the metallization layer, where the seed layer includes a first portion over the conductive feature and a second portion over the field dielectric. Forming the copper feature also includes forming and patterning a mask over the seed layer to form an opening positioned over the conductive feature, where the first portion of the seed layer is exposed through the opening. Forming the copper feature also includes plating copper metal into the opening and over the first portion of the seed layer, removing the mask to expose the second portion of the seed layer, and removing the second portion of the seed layer. In some embodiments, the seed layer includes copper. Removing the second portion of the seed layer can includes comprises etching the second portion of the seed layer.

In some embodiments, the element includes a first element and the hybrid bonding surface includes a first hybrid bonding surface, and the method also includes providing a second element having a second hybrid bonding surface, and hybrid bonding the first hybrid bonding surface to the second hybrid bonding surface.

In some embodiments, the hybrid bonding surface includes a non-conductive field region and a surface of the copper feature. The surface of the copper feature is recessed below the non-conductive field region.

In some embodiments, the dielectric layer includes silicon nitride.

In some embodiments, the dielectric layer includes a first dielectric layer, and the method also includes, after forming the first dielectric layer over the sidewalls of the copper feature, forming a second dielectric layer over the first dielectric layer. The first dielectric layer can include silicon oxide. The second dielectric layer can include silicon nitride. In some arrangements, planarizing the first dielectric layer includes planarizing the first dielectric layer and the second dielectric layer.

In some embodiments, the metallization layer includes a back-end-of-line (BEOL) layer.

In some embodiments, the conductive feature includes a first conductive feature, the copper feature includes a first copper feature, and the metallization layer includes a second conductive feature embedded in the field dielectric. The method also includes, before forming the dielectric layer, forming a second copper feature over the second conductive feature; and forming the dielectric layer over sidewalls of the second copper feature and into a gap between the first and second copper features.

According to another aspect, a method is provided for forming a bonded structure. The method includes providing a first element having a metallization layer that includes a dielectric layer and a plurality of conductive features embedded in the dielectric layer. A bonding layer is formed over the surface of the metallization layer, where the bonding layer includes a dielectric material and a plurality of copper features, and at least one of the copper features is electrically connected to one of the conductive features. The dielectric material and the copper features form a first hybrid bonding surface of the bonding layer, and the dielectric material includes an oxide that directly contacts sidewalls of each of the plurality of copper features. The method also includes preparing the first hybrid bonding surface for hybrid bonding, providing a second element having a second hybrid bonding surface, and hybrid bonding the first hybrid bonding surface to the second hybrid bonding surface.

In some embodiments, forming the bonding layer over the surface of the metallization layer includes forming the plurality of copper features over the plurality of conductive features; and, after forming the plurality of copper features, depositing the dielectric material over the metallization layer such that the sidewalls of each of the plurality of copper features are covered by the dielectric material.

In some embodiments, the copper features include a first copper feature and a second copper feature, and depositing the dielectric material over the metallization layer includes depositing the dielectric material into a gap between the first and second copper features. In some embodiments, the dielectric material includes a first dielectric material and forming the bonding layer over the surface of the metallization layer includes, before forming the copper features, depositing a second dielectric material over the surface of the metallization layer; and forming a plurality of vias in the second dielectric material. Each of the vias is formed over one of the conductive features, and forming the copper features over the conductive features includes filling each of the plurality of vias with copper metal. The method can also include, after forming the plurality of vias in the second dielectric material but before forming the plurality of copper features, forming a barrier layer in each of the plurality of vias such that the barrier layer is formed directly on each of the plurality of conductive features. In some embodiments, filling the vias with the copper metal can include filling each of the vias with the copper metal such that the copper metal is formed on the barrier layer in each of the plurality of vias. In some embodiments, the barrier layer does not contact the sidewalls of each of the plurality of copper features. In some embodiments, filling the vias with the copper metal includes filling each of the vias with the copper metal such that the copper metal is formed directly on the plurality of conductive features.

In some embodiments, forming the plurality of copper features over the plurality of conductive features includes, before forming the plurality of copper features, forming a seed layer over the surface of the metallization layer, wherein the seed layer includes first portions over the plurality of conductive features and second portions over the dielectric layer. A mask is formed over the seed layer, where the mask has having openings positioned over each of the plurality of conductive features, and the first portions of the seed layer are exposed through the openings. Copper metal is plated into the openings and over the first portions of the seed layer. The mask is removed to expose the second portions of the seed layer, and the second portions of the seed layer are removed. In some embodiments, forming the seed layer over the surface of the metallization layer includes forming the seed layer directly on the surface of the metallization layer and removing the second portions of the seed layer includes comprises exposing the dielectric layer. In other embodiments, the dielectric material includes a first dielectric material and forming the bonding layer over the surface of the metallization layer includes, before forming the seed layer over the surface of the metallization layer, depositing a second dielectric material over the surface of the metallization layer; and forming a plurality of vias in the second dielectric material. Each of the vias is formed over one of the conductive features. Forming the seed layer over the surface of the metallization layer includes depositing the copper metal into the vias to form the first portions and depositing the copper metal over the second dielectric material to form the second portions. Removing the second portions of the seed layer includes exposing the second dielectric material.

In some embodiments, the oxide material includes silicon oxide.

In some embodiments, the dielectric material includes the oxide material and the bonding layer includes a second dielectric material formed over the oxide material.

In some embodiments, the sidewalls of each of the copper features includes copper oxide and the dielectric material directly contacts the copper oxide.

In accordance with another aspect, a microelectronic component is provided. The microelectronic component includes an element having a metallization layer including a first dielectric layer and a conductive feature embedded in the first dielectric layer; and a bonding layer formed over the metallization layer. The bonding layer includes a second dielectric layer and a copper feature. The copper feature is electrically connected to the conductive feature. The second dielectric layer directly contacts sidewalls of the copper feature. The second dielectric layer and the copper feature form a hybrid bonding surface of the bonding layer.

In some embodiments, the bonding layer also includes further a barrier layer between the copper feature and the conductive feature. In some embodiments, the barrier layer does not contact the sidewalls of the copper feature. In some embodiments, the barrier layer is formed directly on the conductive feature.

In some embodiments, the bonding layer also includes a third dielectric layer formed between the second dielectric layer and the first dielectric layer. The third dielectric layer can include silicon nitride. The third dielectric layer can include a via, where the copper feature electrically connects to the conductive feature through the via. The bonding layer can also include a seed layer under the copper feature, wherein the seed layer at least partially fills the via.

In some embodiments, the second dielectric layer is formed directly on the first dielectric layer.

In some embodiments, a surface of the copper feature is recessed below a surface of the second dielectric layer.

In some embodiments, the element includes a first element, the hybrid bonding surface includes a first hybrid bonding surface, and the microelectronic component also includes: a second element having a second conductive feature and a fourth dielectric layer that form a second hybrid bonding surface of the second element. The first hybrid bonding surface is hybrid bonded to the second hybrid bonding surface such that the second dielectric layer is directly bonded to the fourth dielectric layer without an intervening adhesive and the copper feature is directly bonded to the second conductive feature with a metal-to-metal direct bond.

In some embodiments, the second dielectric layer includes silicon oxide.

In some embodiments, the second dielectric layer includes multiple layers of different dielectric materials.

In some embodiments, the bonding layer additionally includes a field dielectric formed over the second dielectric layer, where the hybrid bonding surface comprises the field dielectric. The second dielectric layer can include silicon nitride while the field dielectric includes silicon oxide.

In some embodiments, the sidewalls of the copper feature include copper oxide and wherein the second dielectric layer directly contacts the copper oxide.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A method of forming a microelectronic component, the method comprising:
providing an element having a metallization layer that comprises a field dielectric and a conductive feature embedded in the field dielectric;
forming a copper feature over the conductive feature;
after forming the copper feature, forming a dielectric layer over sidewalls of the copper feature; and
planarizing the dielectric layer to form a hybrid bonding surface, wherein the copper feature is exposed at the hybrid bonding surface.

2. The method of claim 1, wherein the dielectric layer comprises silicon oxide and wherein forming the dielectric layer over the sidewalls of the copper feature comprises forming the dielectric layer over the sidewalls of the copper feature such that the silicon oxide directly contacts the sidewalls of the copper feature.

3. (canceled)

4. The method of claim 1, wherein the dielectric layer comprises a first dielectric layer, the method further comprising:
before forming the copper feature over the conductive feature, forming a second dielectric layer over the metallization layer; and
forming a via in the second dielectric layer to expose a portion of the conductive feature through the second dielectric layer, wherein, after forming the copper feature over the conductive feature, at least a portion of the copper feature is within the via.

5. The method of claim 4, further comprising:
after forming the second dielectric layer over the metallization layer but before forming the copper feature over the conductive feature, forming a barrier layer over the second dielectric layer and the portion of the conductive feature; and
after forming the copper feature over the conductive feature, removing a portion of the barrier layer to expose the second dielectric layer.

6. (canceled)

7. (canceled)

8. (canceled)

9. (canceled)

10. (canceled)

11. The method of claim 5, wherein the barrier layer is not formed on the sidewalls of the copper feature.

12. (canceled)

13. (canceled)

14. The method of claim 1, wherein forming the copper feature over the conductive feature comprises:
forming a seed layer over the metallization layer, wherein the seed layer comprises a first portion over the conductive feature and a second portion over the field dielectric;
forming and patterning a mask over the seed layer to form an opening positioned over the conductive feature, wherein the first portion of the seed layer is exposed through the opening;
plating copper metal into the opening and over the first portion of the seed layer;
removing the mask to expose the second portion of the seed layer; and
removing the second portion of the seed layer.

15. (canceled)

16. (canceled)

17. The method of claim 1, wherein the element comprises a first element and the hybrid bonding surface comprises a first hybrid bonding surface, the method further comprising:
providing a second element having a second hybrid bonding surface; and
hybrid bonding the first hybrid bonding surface to the second hybrid bonding surface.

18. (canceled)

19. The method of claim 1, wherein the dielectric layer comprises silicon nitride.

20. The method of claim 1, wherein the dielectric layer comprises a first dielectric layer, the method further comprising:
after forming the first dielectric layer over the sidewalls of the copper feature, forming a second dielectric layer over the first dielectric layer.

21. The method of claim 20, wherein the first dielectric layer comprises silicon oxide and the second dielectric layer comprises silicon nitride.

22. (canceled)

23. (canceled)

24. (canceled)

25. (canceled)

26. A method of forming a bonded structure, the method comprising:
providing a first element having a metallization layer that comprises a dielectric layer and a plurality of conductive features embedded in the dielectric layer;
forming a bonding layer over the surface of the metallization layer, wherein the bonding layer comprises a dielectric material and a plurality of copper features, wherein at least one of the plurality of copper features is electrically connected to one of the plurality of conductive features, wherein the dielectric material and the plurality of copper features form a first hybrid bonding surface of the bonding layer, and the dielectric material comprises an oxide material that directly contacts sidewalls of each of the plurality of copper features;
preparing the first hybrid bonding surface for hybrid bonding;
providing a second element having a second hybrid bonding surface; and
hybrid bonding the first hybrid bonding surface to the second hybrid bonding surface.

27. The method of claim 26, wherein forming the bonding layer over the surface of the metallization layer comprises:
forming the plurality of copper features over the plurality of conductive features; and
after forming the plurality of copper features, depositing the dielectric material over the metallization layer and into gaps between adjacent ones of the plurality of copper features such that the sidewalls of each of the plurality of copper features are covered by the dielectric material.

28. (canceled)

29. The method of claim 27, wherein the dielectric material comprises a first dielectric material and wherein forming the bonding layer over the surface of the metallization layer comprises:
before forming the plurality of copper features, depositing a second dielectric material over the surface of the metallization layer; and
forming a plurality of vias in the second dielectric material, wherein each of the plurality of vias is formed over one of the plurality of conductive features, and wherein forming the plurality of copper features over the plurality of conductive features comprises filling each of the plurality of vias with copper metal.

30. The method of claim 29, further comprising:
after forming the plurality of vias in the second dielectric material but before forming the plurality of copper features, forming a barrier layer in each of the plurality of vias such that the barrier layer is formed directly on each of the plurality of conductive features.

31. (canceled)

32. The method of claim 30, wherein the barrier layer does not contact the sidewalls of each of the plurality of copper features.

33. (canceled)

34. (canceled)

35. (canceled)

36. (canceled)

37. The method of claim 26, wherein the oxide material comprises silicon oxide.

38. (canceled)

39. The method of claim 26, wherein the sidewalls of each of the plurality of copper features comprises copper oxide and wherein the dielectric material directly contacts the copper oxide.

40. A microelectronic component, comprising:
an element having a metallization layer including a first dielectric layer and a conductive feature embedded in the first dielectric layer; and
a bonding layer formed over the metallization layer, wherein the bonding layer comprises:
a second dielectric layer; and
a copper feature, wherein the copper feature is electrically connected to the conductive feature, wherein the second dielectric layer directly contacts sidewalls of the copper feature, and wherein the second dielectric layer and the copper feature form a hybrid bonding surface of the bonding layer.

41. The microelectronic component of claim 40, wherein the bonding layer further comprises:
a barrier layer between the copper feature and the conductive feature, wherein the barrier layer does not contact the sidewalls of the copper feature.

42. (canceled)

43. (canceled)

44. The microelectronic component of claim 40, wherein the bonding layer further comprises:
a third dielectric layer formed between the second dielectric layer and the first dielectric layer wherein the third dielectric layer comprises a via and wherein the copper feature electrically connects to the conductive feature through the via.

45. (canceled)

46. (canceled)

47. (canceled)

48. (canceled)

49. (canceled)

50. The microelectronic component of claim 40, wherein the element comprises a first element, wherein the hybrid bonding surface comprises a first hybrid bonding surface, and wherein the microelectronic component further comprises:
a second element having a second conductive feature and a fourth dielectric layer that form a second hybrid bonding surface of the second element, wherein the first hybrid bonding surface is hybrid bonded to the second hybrid bonding surface such that the second dielectric layer is directly bonded to the fourth dielectric layer without an intervening adhesive and the copper feature is directly bonded to the second conductive feature with a metal-to-metal direct bond.

51. (canceled)

52. (canceled)

53. (canceled)

54. (canceled)

55. The microelectronic component of claim 40, wherein the sidewalls of the copper feature comprise copper oxide and wherein the second dielectric layer directly contacts the copper oxide.
